(19) United States
(12) Patent Application Publication
(10) Pub. No.: US 2022/0107223 A1
(43) Pub. Date: Apr. 7, 2022

(54) MICROELECTRONIC SENSOR WITH BOLOMETRIC OR PYROELECTRIC DETECTOR FOR SENSING ELECTRICAL SIGNALS IN SUB-TERAHERTZ AND TERAHERTZ FREQUENCY RANGES

(71) Applicant: Ram THZ Solutions Pte. Ltd., Singapore (SG)

(72) Inventors: Ayal RAM, Singapore (SG); Walid-Madhat MUNIEF, Blieskastel (DE)

(21) Appl. No.: 17/516,946

(22) Filed: Nov. 2, 2021

Related U.S. Application Data
(63) Continuation-in-part of application No. PCT/IB2020/054060, filed on Apr. 30, 2020.
(60) Provisional application No. 62/841,955, filed on May 2, 2019.

(51) Int. Cl. G01J 5/24; G01J 5/02; G01J 5/34

(52) U.S. Cl. CPC G01J 5/24; G01J 5/34; G01J 5/0215

(57) ABSTRACT

The present invention relates to an open-gate pseudo-conducting high-electron mobility transistor (PC-HEMT) combined with a bolometric or pyroelectric detector installed in an open gate area of the transistor, for amplifying signals in the frequency range between 30 GHz to 430 THz. The transistor of the present invention further comprises either an asymmetric dual grating gate created on top of a detector layer, or a separately-biased grating gate created on top and in the middle of the detector layer. The grating gate is capable of completely depleting the 2DEG or 2DHG conducting channel locally, while leaving the remaining area under the grating gate to be tuned for resonant plasmon absorption of sub-THz or THz radiation. A microelectronic sensor comprising the PC-HEMT of the present invention is suitable for chemical sensing and biomolecular diagnostics. Non-limiting examples of biological compounds to be tested are human viral pathogens, such as SARS-CoV-2.

### CROSS REFERENCE TO RELATED APPLICATIONS

This application is a Continuation in Part of PCT Patent Application No. PCT/IB2020/054060 having an international filing date of Apr. 30, 2020, which claims the benefit of priority of U.S. Provisional Patent Application No. 62/841,955, filed May 2, 2019, the contents of which are all incorporated herein by reference in their entirety.

### TECHNICAL FIELD

The present application relates to the field of microelectronic sensors based on high-electron-mobility transistors and their use in detection and continuous monitoring of electrical signals in sub-terahertz and terahertz frequency ranges. In particular, the present application relates to the microelectronic sensor combining an open-gate pseudo-conducting high-electron-mobility transistor (PC-HEMT) and bolometric or pyroelectric detector.

### BACKGROUND

### Sub-THz and THz Spectroscopy

Recently it has become clear to scientists that sub-terahertz (sub-THz) and terahertz (THz) radiation could be extremely important for research related to the life sciences because of the unique capability of these low energy electromagnetic waves to interact with vibrations of atoms within biological molecules to produce specific molecular fingerprints (see for example, Globus et al. in “Terahertz Fourier transform characterization of biological materials in a liquid phase”, J. Physics D: Applied Physics, 39(15), 3405-3413). Sub-THz and THz spectroscopy uses wavelengths beyond those traditionally used for chemical and biomolecular analysis. Biological materials have found to be active in the frequency range of 30 GHz to 430 THz. These frequency and wavelength domains, the spectral range between the upper end of the radio frequencies and microwaves and the lowest optical frequencies were named the ‘Terahertz Gap’, because so little was known about them and because of the absence of radiation sources and detectors.

Sub-THz and THz vibrational spectroscopy is entirely based on the interaction of radiation in this particular frequency range with internal molecular vibrations of low energy. A majority of the sub-THz and THz experimental data have recently been reported on frequencies in this range and for relatively small biological molecules that are often prepared in crystalline form (for example, Heilweil et al. (2008), “Terahertz Spectroscopy of Biomolecules”, In Terahertz Spectroscopy, Taylor and Francis, London, 2008, Chapter 7, pp 269-297). Low-energy THz radiation interacts with the low-frequency internal molecular motions (vibrations) involving the weakest hydrogen bonds (H-bonds) and other weak connections within molecules by exciting these vibrations. The width of individual spectral lines and the intensity of resonance features, which are observed in sub-THz spectroscopy, are very sensitive to the relaxation processes of atomic dynamics (displacements) within a molecule. Those relaxation processes determine the discriminative capabilities of sub-THz spectroscopy. Appropriate spectral resolution must be used in THz spectroscopy to be able to acquire qualitative as well as quantitative information used to identify the molecules that will, in turn, increase detection accuracy and selectivity.

Because of their small size and relatively low absorption coefficient, the waves of the sub-THz and THz radiation easily propagate through any liquid, such as water, serum or any biological medium including the entire biological object, for example cells and skin. Safrai et al. (2012) in “The remote sensing of mental stress from the electromagnetic reflection coefficient of human skin in the sub-THz range”, Bioelectromagnetics, 2012, 33(5), 375-82, and Safrai et al. (2014-1) in “Remote monitoring of phasic heart rate changes from the palm” in IEEE Transactions on Terahertz Science and Technology, 2014, 4, 618-624, reported that both physical and mental stress could be traced through the reflection coefficient of the hand, influenced by the activity of the sweat ducts, in the (75 GHz-110 GHz) and (110 GHz-170 GHz) frequency bands. The reflected signal was monitored from a distance of 72 cm using a Vector Network Analyser, while the patients' electrocardiograms (ECGs) were concurrently registered. Further, Safrai et al. (2014-2) in “The correlation of ECG parameters to the sub-THz reflection coefficient of human skin”, IEEE Transactions on Terahertz Science and Technology, 2014, 4(5), 624-630, reported on a good correlation between the reflection coefficient in the same frequency bands and some of the parameters of the ECG, mainly to the ST elevation.

### High Electron Mobility Transistors

Polarisation-doped high-electron-mobility transistor (HEMT) is a field effect transistor in which two layers of different bandgap and polarisation field are grown upon each other forming the heterojunction structure. This transistor is essentially based on at least two layers of III-V semiconductor materials, such as gallium nitride (GaN) and aluminium gallium nitride (AlGaN). As a consequence of the discontinuity in the polarisation field, surface charges are created at the interface between the layers. If the induced surface charge is positive, electrons will tend to compensate the induced charge resulting in the formation of the channel. Since the channel electrons are confined in a quantum well in an infinitely narrow spatial region at the interface between the layers, these electrons are referred to as a two-dimensional electron gas (2DEG). This special confinement of the channel electrons in the quantum well actually grants them two-dimensional features, which strongly enhance their mobility surpassing the bulk mobility of the material in which the electrons are flowing.

FIGS. 1a-1c schematically shows the quantum well at three different biasing conditions starting from the positive gate potential (V_{G}), much higher than the threshold voltage (V_{T}), and going down to the 0V gate potential and further to the negative values below the threshold voltage. The V_{T} is defined as a voltage, which is required to populate electrons at the interface between the GaN layer and the AlGaN layers, thereby creating conductivity of the 2DEG channel. Since the 2DEG channel electrons occupy energy levels below the Fermi level, the Fermi level in a quantum well is located above several energy levels when V_{G}>>V_{T} (FIG. 1a). This enables high population of channel electrons and consequently, high conductivity. The 2DEG channel is turned on in this case. However, when V_{G} decreases to 0V (FIG. 1b), the Fermi level also drops with respect to the quantum well. As a result, much fewer electron energy levels are populated and the amount of the 2DEG channel electrons significantly decreases. When V_{G} much less than V_{T} (FIG. 1c), all electron energy levels are above the Fermi level, and there is no the 2DEG electrons below the gate. This situation is called “channel depletion”, and the channel is turned off.

Many commercially available HEMTs based on the layers of III-V semi-conductor materials have a negative value of V_{T}, resulting in a “normally-on” operation mode at 0V gate potential. They are called “depletion-mode” semiconductor transistors and used in various power switching applications when the negative voltage must be applied on the gate in order to block the current. However, for safe operation at high voltage or high power density, in order to reduce the circuit complexity and eliminate standby power consumption, the transistors with “normally-off” characteristics are preferred. The high voltages and high switching speeds allow smaller, more efficient devices, such as home appliances, communications and automobiles to be manufactured. To control the density of electrons in the 2DEG channel and to switch the HEMT on and off, the voltage at the gate of the transistor is normally regulated.

Several techniques to manufacture the normally-off semiconductor structures have been reported. Burnham et al (2010) proposed normally-off structures of the recessed gate type. In this structure, the AlGaN barrier layer is etched and the gate is brought closer to the interface between the AlGaN barrier layer and the GaN buffer layer. As the gate approaches the interface between the layers, the V_{T} increases. Thus, the normally-off operation of the 2DEG conducting channel is achieved once the depletion region reaches the interface and depletes the 2DEG channel at zero gate voltage. The major advantages of these structures are relatively lower power consumption, lower noise and simpler drive circuits. They are currently used, for example, in microwave and millimetre wave communications, imaging and radars.

Chang et al (2009) proposed instead of etching the relatively thick barrier layer to approach the AlGaN/GaN interface, to use a very thin AlGaN barrier. This structure also achieves the normally-off operation of the 2DEG channel by approaching the gate towards the AlGaN/GaN interface. Chen et al (2010) proposed to use the fluorine-based plasma treatment method. Although many publications have adopted various methods to achieve normally-off devices with minimum impact on the drain current, they unfortunately sacrificed device turn-on performance.

### SUMMARY

The present application describes embodiments of an open-gate pseudo-conducting high-electron mobility transistor (PC-HEMT) combined with a bolometric or pyroelectric detector installed in an open gate area of the transistor, for amplifying signals in the frequency range between 30 GHz to 430 THz. In one embodiment, the PC-HEMT of the present invention comprises:
(1) a multilayer hetero-junction structure made of gallium nitride (GaN) and aluminium gallium nitride (AlGaN) single-crystalline or polycrystalline semi-conductor materials, deposited on a substrate layer or placed on a free-standing membrane, said structure comprising at least one GaN layer and at least one AlGaN layer, said layers being stacked alternately;
(2) a conducting channel comprising a two-dimensional electron gas (2DEG) or a two-dimensional hole gas (2DHG), formed at the interface between said GaN layer and said AlGaN layer, and upon applying a bias to said transistor, providing electron or hole current, respectively, in said transistor between source and drain contact areas;
(3) the source and drain contacts connected to said 2DEG or 2DHG conducting channel and to electrical metallisations for connecting said transistor to an electric circuit; and
(4) a bolometric or pyroelectric detector placed on a top layer (GaN or AlGaN) between said source and drain contacts in an open gate area of the transistor, and suitable for detecting electrical signals in the frequency range of 30 GHz to 430 THz;
wherein thickness of the top layer (GaN or AlGaN) of said heterojunction structure in the open gate area is about 5-9 nanometres (nm) and surface roughness of said top layer is about 0.2 nm or less,
   wherein the combination of said thickness and said roughness of the top layer creates a quantum electronic effect of operating said 2DEG or 2DHG channel simultaneously in both normally-on and normally-off operation modes of the channel, thereby making the transistor suitable for conducting electric current through said channel in a quantum well between normally-on and normally-off operation modes of the transistor.

In another embodiment, the transistor of the present invention further comprises either an asymmetric dual grating gate created on top of the detector layer, or a separately-biased grating gate created on top and in the middle of the detector layer. The grating gate is capable of completely depleting the 2DEG or 2DHG conducting channel locally, while leaving the remaining area under the grating gate to be tuned for resonant plasmon absorption of sub-THz or THz radiation.

In some embodiments, said transistor further comprises at least one molecular or bio-molecular layer immobilised on the detector layer within the open gate area of said transistor and capable of binding or adsorbing target (analyte) gases, chemical compounds or biomolecules from the environment. In another embodiment, the transistor is not coated with a molecular or biomolecular layer and is capable of remotely detecting target (analyte) gases, chemical compounds or biomolecules from the environment.

In a further embodiment, the source and drain contacts of said transistor are ohmic. In a particular embodiment, the electrical metallisations of said transistor are capacitively-coupled to said 2DEG or 2DHG conducting channel for inducing displacement currents, thus resulting in said source and drain contacts being non-ohmic. In this case, since the source and drain contacts are non-ohmic, the DC readout cannot be done. Instead, to electrically contact the 2DEG/2DHG channel underneath, about 5-20 nm bellow the metallisations, the AC readout or impedance measurements of the electric current flowing through the 2DEG/2DHG-channel must be performed. In this case, the capacitive coupling of the non-ohmic metal contacts with the 2DEG/2DHG channel is normally induced at the frequency higher than 30 kHz.

In a particular embodiment, said transistor further comprises a dielectric layer deposited on top of said multilayer hetero-junction structure. In another particular embodiment, the thickness of the top layer recessed in the open gate area of said transistor is 6-7 nm, more specifically 6.2 nm to 6.4 nm. The surface roughness of the top layer recessed in the open gate area of said transistor is specifically 0.1 nm or less, more specifically 0.05 nm or less.

Non-limiting examples of the molecular or biomolecular layer of said transistor is a cyclodextrin, 2,2,3,3-tetrafluoropropyloxy-substituted phthalocyanine or their derivatives, or said molecular or biomolecular layer comprises capturing biological molecules, such as primary, secondary antibodies or fragments thereof against certain proteins to be detected, or their corresponding antigens, enzymes or their substrates, short peptides, specific DNA sequences, which are complimentary to the sequences of DNA to be detected, aptamers, receptor proteins or molecularly imprinted polymers.

In a further embodiment, said microelectronic sensor is suitable for use in detection and continuous monitoring of electrical signals in the frequency range between 30 GHz to 430 THz and consequently, for chemical sensing and biomolecular diagnostics in said frequency range, said sensor having a remote readout and comprising:
(a) at least one PC-HEMT (100) of the present invention;
(b) an integrated circuit (101) for storing and processing a signal in a sub-THz or THz frequency domain, and for modulating and demodulating a radio-frequency (RF) signals;
(c) an μ-pulse generator (102) for pulsed RF signal generation;
(d) an integrated DC-RF current amplifier or lock-in amplifier (103) connected to said μ-pulse generator (102) for amplification of the signal obtained from said μ-pulse generator;
(e) an analogue-to-digital converter (ADC) (104) with in-built digital input/output card connected to the amplifier (103) for converting the received analogue signal to a digital signal and outputting said digital signal to a microcontroller unit;
(f) the microcontroller unit (MCU) (105) for processing and converting the received digital signal into data readable in a user interface or external memory; and
(g) a wireless connection module (106) for wireless connection of said microelectronic sensor to said user interface or external memory.

In yet further embodiment, said microelectronic sensor is suitable for use in detection and continuous monitoring of electrical signals in the frequency range of 30 GHz to 430 THz and consequently, for chemical sensing and biomolecular diagnostics in said frequency range, said sensor having a remote readout and comprising:
(a) an array (110) of the PC-HEMTs (100) of the present invention, each transistor (100) in said array (110) is connected to its dedicated electrical contact line;
(b) a row multiplexer (107) connected to said array (110) for addressing a plurality of said transistors (100) arranged in rows, selecting one of several analogue or digital input signals and forwarding the selected input into a single line;
(c) a column multiplexer (108) connected to said array (110) for addressing a plurality of said transistors (100) arranged in columns, selecting one of several analogue or digital input signals and forwarding the selected input into a single line;
(d) an integrated circuit for storing and processing said signals in a sub-THz or THz frequency domain, and for modulating and demodulating a radio-frequency (RF) signals;
(e) an μ-pulse generator (102) for pulsed RF signal generation;
(f) an integrated DC-RF current amplifier or lock-in amplifier (103) connected to said μ-pulse generator (102) for amplification of the signal obtained from said μ-pulse generator;
(g) an analogue-to-digital converter (ADC) (104) with in-built digital input/output card connected to the amplifier (103) for converting the received analogue signal to a digital signal and outputting said digital signal to a microcontroller unit;
(h) the microcontroller unit (MCU) (105) for processing and converting the received digital signal into data readable in a user interface or external memory; and
(i) a wireless connection module (106) for wireless connection of said microelectronic sensor to said user interface or external memory.

The sample can be either in a gas phase or in a liquid phase. In a further embodiment, the present application provides a method for chemical sensing and biomolecular diagnostics using the microelectronic sensor of the present invention.

Non-limiting examples of the chemicals to be tested are a toxic metal, such as chromium, cadmium or lead, a regulated ozone-depleting chlorinated hydrocarbon, a food toxin, such as aflatoxin, or shellfish poisoning toxin, such as saxitoxin or microcystin, a neurotoxic compound, such as methanol, manganese glutamate, nitrix oxide, Botox, tetanus toxin or tetrodotoxin, oxybenzone, Bisphenol A, or butylated hydroxyanisole, an explosive, such as picrate, nitrate, trinitro derivative, such as 2,4,6-trinitrotoluene (TNT), 1,3,5-trinitro-1,3,5-triazinane (RDX), trinitroglycerine, N-methyl-N-(2,4,6-trinitrophenyl)nitramide (nitramine or tetryl), pentaerythritol tetranitrate (PETN), nitric ester, azide, derivate of chloric and perchloric acids, fulminate, acetylide, and nitrogen rich compound, such as tetrazene, octahydro-1,3,5,7-tetranitro-1,3,5,7-tetrazocine (HMX), peroxide, such as triacetone trioxide, C4 plastic explosive and ozonidesor, or an associated compound of said explosive, such as a decomposition gas or taggant, or an opioid, such as fentanyl, methamphetamine, heroin or a cocaine-based opiate.

Non-limiting examples of biological compounds to be tested are biological pathogens, such as respiratory viral or bacterial pathogens, airborne pathogens, plant pathogens, pathogen from infected animals or human viral pathogens. The specific example of the human viral pathogen to be detected is SARS-CoV-2.

Various embodiments may allow various benefits, and may be used in conjunction with various applications. The details of one or more embodiments are set forth in the accompanying figures and the description below. Other features, objects and advantages of the described techniques will be apparent from the description and drawings and from the claims

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Disclosed embodiments will be understood and appreciated more fully from the following detailed description taken in conjunction with the appended figures. The drawings included and described herein are schematic and are not limiting the scope of the disclosure. It is also noted that in the drawings, the size of some elements may be exaggerated and, therefore, not drawn to scale for illustrative purposes. The dimensions and the relative dimensions do not necessarily correspond to actual reductions to practice of the disclosure.

FIGS. 1a, 1b, and 1c schematically show the quantum well at three different biasing conditions, as follows:

FIG. 1a: positive gate potential (+VG) is much higher than threshold voltage (V_{T}),

FIG. 1b: 0V gate potential, and

FIG. 1c: negative gate potential (−VG) is below threshold voltage (V_{T}).

FIG. 2a schematically shows a cross-sectional (XZ) view (A-A) of the PC-HEMT of the present invention.

FIG. 2b schematically shows a cross-sectional (XZ) view (A-A) of the PC-HEMT of the present invention with ohmic contacts and with the heterojunction structure placed on free-standing membranes.

FIG. 2c illustrates a situation when the external pressure (mass effect) is applied on the transistor of FIG. 2a and transferred into a changed internal strain caused by bending.

FIG. 2d schematically shows a cross-sectional (XZ) view (A-A) of the PC-HEMT of the present invention with non-ohmic contacts and with the heterojunction structure placed on free-standing membranes.

FIG. 2e schematically shows an expanded cross-sectional (XZ) view (A-A) of an exemplary bolometric or pyroelectric detector (16) of the PC-HEMT of embodiments. The detector (16) of this exemplary embodiment has a three-layer structure based on graphene layer (19) coated with a dielectric band-pass filter (20) and deposited on an alumina layer (18).

FIG. 2f schematically shows the top (XY) view and the basic topology of the exemplary transistor of the present invention shown in FIG. 2a, with the bolometric or pyroelectric detector (16).

FIG. 3 schematically shows the dependence of the source-drain current (a charge carrier density) induced inside the 2DEG channel of a GaN/AlGaN HEMT on the thickness of the AlGaN layer recessed in the open gate area.

FIG. 4 illustrates a theory behind the 2DEG formation (charge neutrality combined with the lowest energy level) at the conduction band discontinuity.

FIG. 5a schematically shows the 2DEG area created in the step of the 2DEG-pattering via ion implantation during the manufacturing process. AZ 4533 is a positive thick resist.

FIG. 5b shows the lithographic mask of the sensor layout of the present invention.

FIG. 5c shows the lithographic image of the 2DEG channel formed with AZ 4533 thick resist lithography over the mask shown in FIG. 5b.

FIGS. 5d-5e show the mask and the corresponding lithographic image, respectively, of the sensor layout of the present invention.

FIG. 5f shows the ±2-μm alignment precision on 25×25 mm2 samples in the lithography of the sensor layout of the present invention.

FIG. 5g shows the lithographic images of the multichannel samples.

FIG. 5h shows the fixed sample on the Si—GaN/AlGaN wafer prepared for ion implantation and containing around 30-32 sensors with 4-8 channels on each sample.

FIG. 5i shows the lithographic image of the sensor layout with the AZ4533 resist after development, prepared for ion implantation.

FIG. 5j shows the 2DEG channels (dark) patterned by ion-implantation after the resist removal.

FIG. 5k shows the visible non-implanted area containing the conductive 2DEG channel.

FIG. 6a shows an exemplary AFM surface image of the top recessed layer of the PC-HEMT made by the manufacturing process of the present invention. The measured RMS value of the surface roughness is 0.674 nm in this example.

FIG. 6b shows the AFM surface image of the top recessed layer of the HEMT made by a conventional manufacturing process. The measured RMS value of the surface roughness is 1.211 nm in this case.

FIG. 6c shows the time-dependent plot of the drain-source electric current I_{DS} of the nitrogen oxide sensor of the present invention measuring 100 ppb of the NO₂ gas in humid air, where the sensor is based on the PC-HEMT made by the manufacturing process of the present invention.

FIG. 6d shows the time-dependent plot of the drain-source electric current I_{DS} of the nitrogen oxide sensor measuring 100 ppb of the NO₂ gas in humid air, where the sensor is based on the HEMT made by a conventional manufacturing process.

FIG. 7a schematically shows the formation of the 2DEG and 2DHG conducting channels in the Ga-face three-layer Ga/AlGaN/GaN PC-HEMT structure.

FIG. 7b schematically shows the formation of the 2DEG and 2DHG conducting channels in the N-face three-layer Ga/AlGaN/GaN PC-HEMT structure.

FIG. 8 schematically shows the formation of the 2DEG conducting channel in the N-face three-layer GaN/AlGaN/GaN PC-HEMT structure with an ultrathin Al(GaN)N layer for improved confinement.

FIG. 9 schematically shows a thermal microbolometer detector.

FIG. 10a schematically shows a phonon-cooled hot bolometric mechanism.

FIG. 10b schematically shows a diffusion-cooled hot bolometric mechanism.

FIG. 11a schematically shows a cross-sectional (XZ) view (A-A) of the PC-HEMT of the present invention, having asymmetric dual grating gate (23) created on top of the detector (16).

FIG. 11b schematically shows the top (XY) view and the basic topology of the exemplary transistor of the present invention shown in FIG. 11a.

FIG. 12a schematically showing a cross-sectional (XZ) view (A-A) of the PC-HEMT of the present invention, with the detector (16) and the gate (24) created on top of the detector (16).

FIG. 12b schematically shows the top (XY) view and the basic topology of the exemplary transistor of the present invention shown in FIG. 12a.

FIG. 13 schematically shows a microelectronic sensor comprising a single PC-HEMT of the embodiments with the integrated bolometric or pyroelectric detector, for detection and continuous monitoring of electrical signals in sub-THz and THz frequency ranges, with a remote readout.

FIG. 14 schematically shows a microelectronic sensor comprising an array of the PC-HEMTs of the embodiments with the integrated bolometric or pyroelectric detector, for detection and continuous monitoring of electrical signals in sub-THz and THz frequency ranges, with a remote readout.

FIG. 15 shows the simulated results obtained by the present inventors for Reσ_{ω}, as functions of time and frequency with momentum relaxation time of 10 ps.

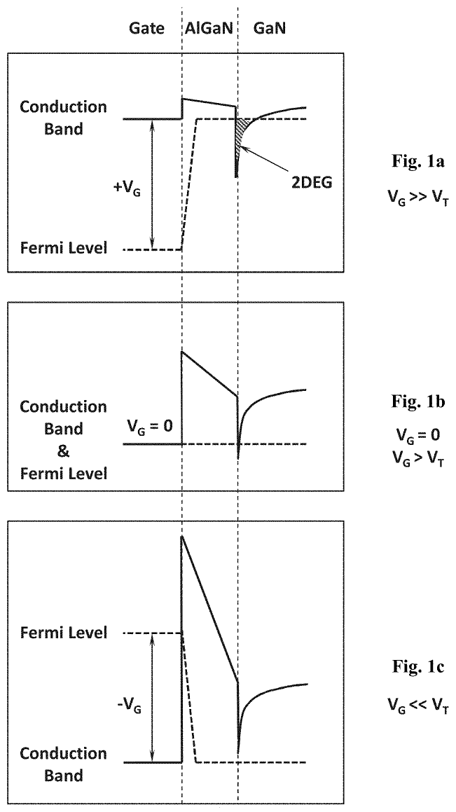

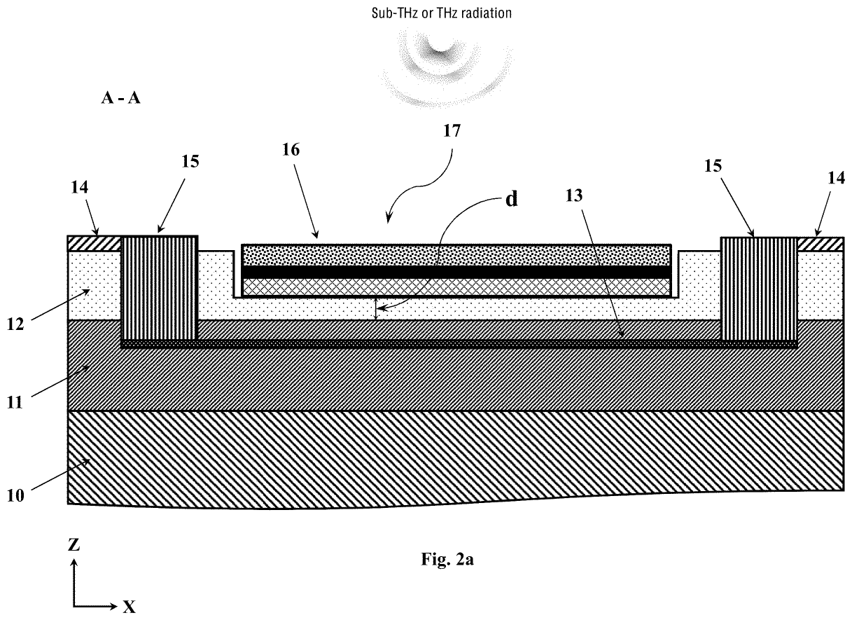

### DETAILED DESCRIPTION

In the following description, various aspects of the present application will be described. For purposes of explanation, specific configurations and details are set forth in order to provide a thorough understanding of the present application. However, it will also be apparent to one skilled in the art that the present application may be practiced without the specific details presented herein. Furthermore, well-known features may be omitted or simplified in order not to obscure the present application.

The term “comprising”, used in the claims, is “open ended” and means the elements recited, or their equivalent in structure or function, plus any other element or elements which are not recited. It should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising x and z” should not be limited to devices consisting only of components x and z. Also, the scope of the expression “a method comprising the steps x and z” should not be limited to methods consisting only of these steps.

Unless specifically stated, as used herein, the term “about” is understood as within a range of normal tolerance in the art, for example within two standard deviations of the mean. In one embodiment, the term “about” means within 10% of the reported numerical value of the number with which it is being used, preferably within 5% of the reported numerical value. For example, the term “about” can be immediately understood as within 10%, 9%, 8%, 7%, 6%, 5%, 4%, 3%, 2%, 1%, 0.5%, 0.1%, 0.05%, or 0.01% of the stated value. In other embodiments, the term “about” can mean a higher tolerance of variation depending on for instance the experimental technique used. Said variations of a specified value are understood by the skilled person and are within the context of the present invention. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges, for example from 1-3, from 2-4, and from 3-5, as well as 1, 2, 3, 4, 5, or 6, individually. This same principle applies to ranges reciting only one numerical value as a minimum or a maximum. Unless otherwise clear from context, all numerical values provided herein are modified by the term “about”. Other similar terms, such as “substantially”, “generally”, “up to” and the like are to be construed as modifying a term or value such that it is not an absolute. Such terms will be defined by the circumstances and the terms that they modify as those terms are understood by those of skilled in the art. This includes, at very least, the degree of expected experimental error, technical error and instrumental error for a given experiment, technique or an instrument used to measure a value.

As used herein, the term “and/or” includes any and all combinations of one or more of the associated listed items. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached to”, “connected to”, “coupled with”, “contacting”, etc., another element, it can be directly on, attached to, connected to, coupled with or contacting the other element or intervening elements may also be present. In contrast, when an element is referred to as being, for example, “directly on”, “directly attached to”, “directly connected to”, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

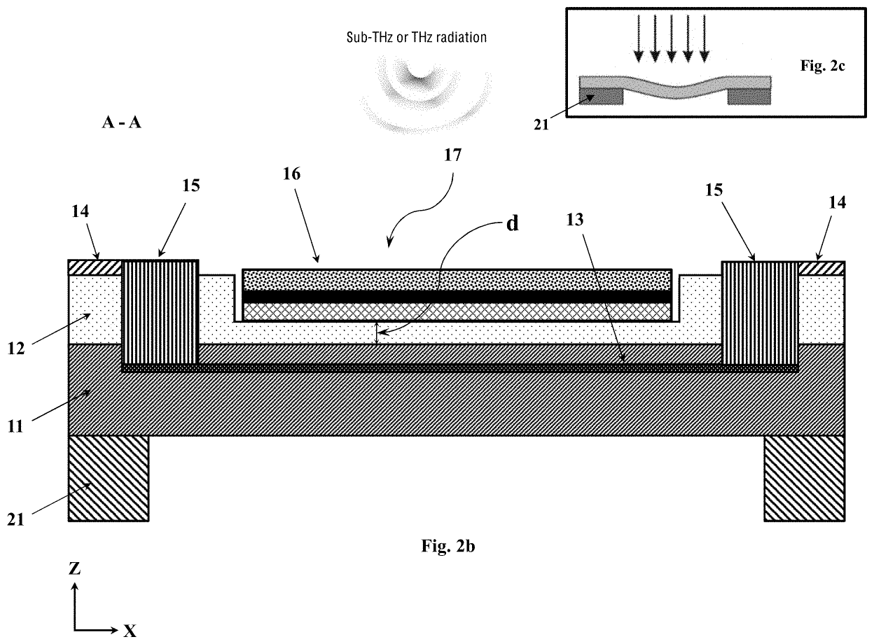

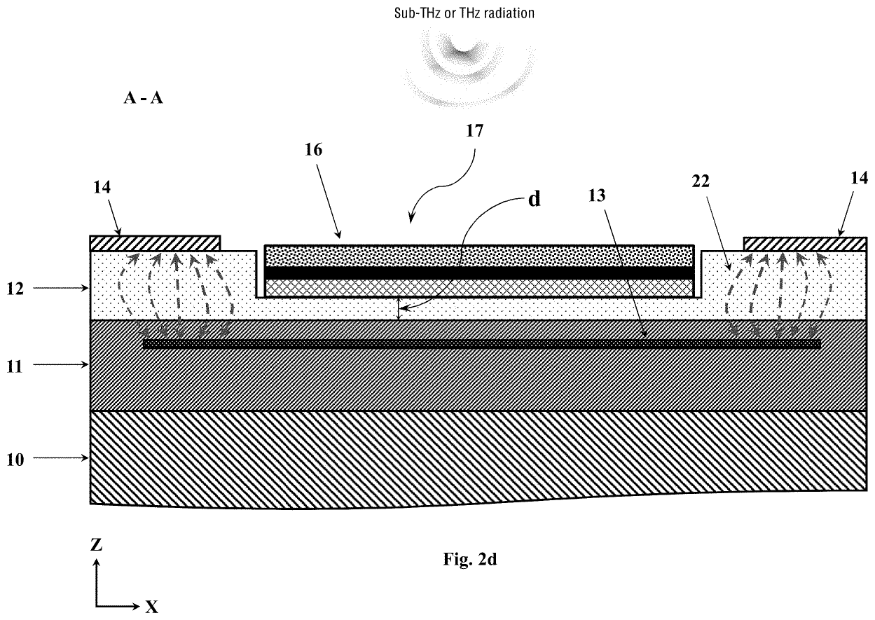

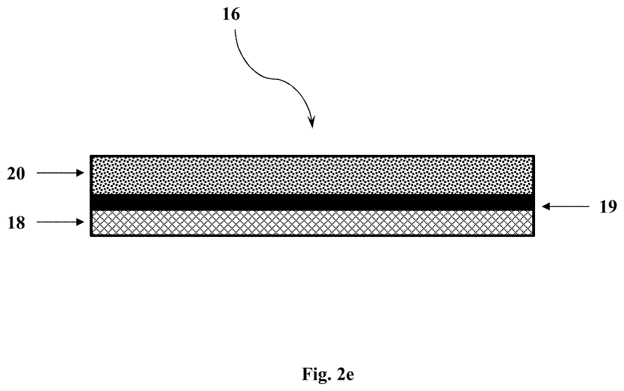

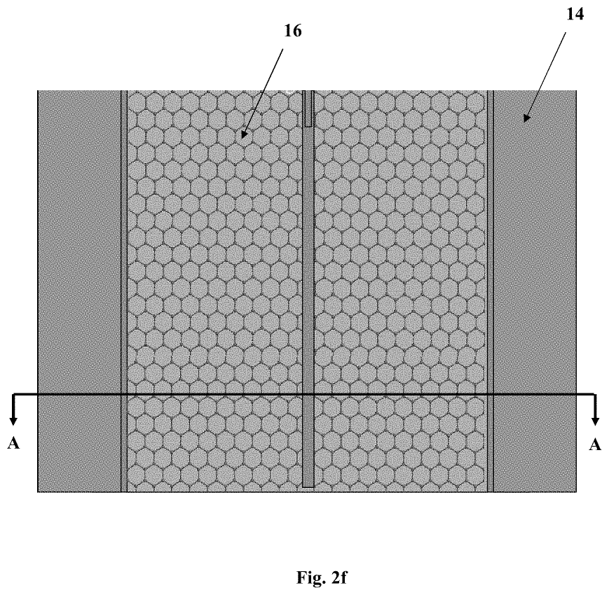

As shown in FIG. 2a, the present application describes embodiments of an open-gate pseudo-conducting high-electron mobility transistor (PC-HEMT) combined with a bolometric or pyroelectric detector installed in an open gate area of the transistor, for amplifying signals in the frequency range between 30 GHz to 430 THz. In one embodiment, the PC-HEMT of the present invention comprises:
(1) a multilayer hetero-junction structure made of gallium nitride (GaN) and aluminium gallium nitride (AlGaN) single-crystalline or polycrystalline semi-conductor materials, deposited on a substrate layer (10) or placed on a free-standing membrane (21), said structure comprising at least one buffer layer (11) and at least one barrier layer (12), said layers being stacked alternately;
(2) a conducting channel (13) comprising a two-dimensional electron gas (2DEG) or a two-dimensional hole gas (2DHG), formed at the interface between said buffer layer (11) and said barrier layer (12), and upon applying a bias to said transistor, providing electron or hole current, respectively, in said transistor between source and drain contact (15) areas;
(3) the source and drain contacts (15) connected to said 2DEG or 2DHG channel (13) and to electrical metallisations (14) for connecting said transistor to an electric circuit; and
(4) a bolometric or pyroelectric detector (16) placed on a top layer between said source and drain contact (15) areas in an open gate area (17) of the transistor, and capable of detecting electrical signals in the frequency range of 30 GHz to 430 THz;
   wherein thickness of the top layer of said multilayer heterojunction structure in the open gate area (17) is 5-9 nanometres (nm) and surface roughness of said top layer is 0.2 nm or less, wherein the combination of said thickness and said roughness of the top layer creates a quantum electronic effect of operating said 2DEG or 2DHG channel simultaneously in both normally-on and normally-off operation modes of the channel, thereby making the transistor suitable for conducting electric current through said channel in a quantum well between normally-on and normally-off operation modes of the transistor.

The PC-HEMT in FIG. 2b with free-standing membranes (21) may be used in “pressure-sensitive” sensors of the present invention, which are capable of measuring very small pressures. These sensors use the free-standing membranes for creating a mass-loading effect which makes it possible to increase selectivity of the sensors via adding mechanical stress (mass-loading effect) as an additional parameter of the PC-HEMT-based sensor. The free-standing membranes (21) are very flexible free-standing columns of substrate composed of sapphire, silicon, silicon carbide, gallium nitride or aluminium nitride, preferably gallium nitride, having thickness of 0.5-2 μm. The free-standing substrate membranes are very sensitive to any tensile, compressive or mechanical stress changes on the surface of the multilayer hetero-junction structure. This results in a mass loading effect, which will be discussed below.

In general, mechanical sensors, much like pressure sensors, are based on the measurement of the externally induced strain in the heterostructures. The pyroelectric properties of group-III-nitrides, such as gallium nitride (GaN), allow two mechanisms for strain transduction: piezoelectric and piezoresistive. The direct piezoelectric effect is used for dynamical pressure sensing. For measurements of static pressure, such sensors are not suitable due to some leakage of electric charges under the constant conditions. For static operation, the piezoresistive transduction is more preferable.

Piezoresistive sensors using wide band gap materials have been previously employed using hexagonal silicon carbide bulk materials for high temperature operation. The piezoresistivity of GaN and AlGaN structures was found to be comparable to silicon carbide. However, piezoresistivity can be further amplified by HEMT structure, as taught by Martin Eickhoff et al in “Piezoresistivity of AlₓGa₁₋ₓN layers and AlₓGa₁₋ₓN/GaN heterostructures”, Journal of Applied Physics 90, 2001, 3383.

For piezoresistive strain sensing at relatively lower pressures (or pressure differences), diaphragm or membranes should be used, where the external pressure is transferred into a changed internal strain caused by bending, as shown in FIG. 2c. The resulting change in polarisation alters the 2DEG channel current which is measured.

Eickhoff et al (2001) conducted the first experiments on AlGaN/GaN hetero-structures where the 2DEG channel confined between the upper GaN and AlGaN barrier layer and demonstrated the linear dependence of the 2DEG channel resistivity on the applied strain. Moreover, a direct comparison to cubic SiC and a single AlGaN layer clearly demonstrated the superior piezoresistive properties of the latter. From these results, it is clear that the interaction of piezoelectric and piezoresistive properties improves the sensitivity of pressure sensors by using GaN/AlGaN heterostructures confined with the 2DEG channel.

Thus, the PC-HEMT configuration which is schematically shown in FIGS. 2b-2c involves piezoelectrically coupled, charge and mass sensitive, free-standing GaN membranes, which are prepared, for example, according to U.S. Pat. No. 8,313,968, and offer an elegant and effective solution to achieve both downscaling and an integrated all-electrical low-power sensing-actuation. As mentioned above, GaN exhibits both, piezo- and pyro-electrical properties, which can be functionally combined. Whereas the piezoelectricity enables realisation of an integrated coupling mechanism, the 2DEG additionally delivers a pronounced sensitivity to mechanical stress and charge, which allows the sensor to use the pyroelectric effects. The dynamic change in 2DEG conductivity is also caused by a change in piezoelectric polarisation.

Another important feature of the sensor of the present application is that an electrical connection of the heterojunction structure to the 2DEG or 2DHG channel is realised either via ohmic source and drain contacts (FIGS. 2a-2b) or via capacitive coupling (FIG. 2d) to the electrical metallisations through a Schottky barrier contact. “Capacitive coupling” is defined as an energy transfer within the same electric circuit or between different electric circuits by means of displacement currents induced by existing electric fields between circuit/s nodes. In general, ohmic contacts (15) are the contacts that follow Ohm's law, meaning that the current flowing through them is directly proportional to the voltage. Non-ohmic contacts (22) however do not follow the same linear relationship of the Ohm's law. In other words, electric current passing through non-ohmic contacts (22) is not linearly proportional to voltage. Instead, it gives a steep curve with an increasing gradient, since the resistance in that case increases as the electric current increases, resulting in increase of the voltage across non-ohmic contacts (22). This is because electrons carry more energy, and when they collide with atoms in the conducting channel, they transfer more energy creating new high-energy vibrational states, thereby increasing resistance and temperature.

When electrical metallisations are placed over single-crystalline or poly-crystalline semiconductor material, the “Schottky contact” or “Schottky barrier contact” between the metal and the semiconductor occurs. Energy of this contact is covered by the Schottky-Mott rule predicting the energy barrier between a metal and a semiconductor to be proportional to the difference of the metal-vacuum work function and semiconductor-vacuum electron affinity. However, this is an ideal theoretical behaviour, while in reality most interfaces between a metal and a semiconductor follow this rule only to some degree. The boundary of a semiconductor crystal abrupt by a metal creates new electron states within its band gap. These new electron states induced by a metal and their occupation push the centre of the band gap to the Fermi level. This phenomenon of shifting the centre of the band gap to the Fermi level as a result of a metal-semiconductor contact is defined as “Fermi level pinning”, which differs from one semiconductor to another. If the Fermi level is energetically far from the band edge, the Schottky contact would preferably be formed. However, if the Fermi level is close to the band edge, an ohmic contact would preferably be formed. The Schottky barrier contact is a rectifying non-ohmic contact, which in reality is almost independent of the semi-conductor or metal work functions.

Thus, a non-ohmic contact allows electric current to flow only in one direction with a non-linear current-voltage curve that looks like that of a diode. On the contrary, an ohmic contact allows electric current to flow in both directions roughly equally within normal device operation range, with an almost linear current-voltage relationship that comes close to that of a resistor (hence, “ohmic”).

If the source and drain contacts are non-ohmic (capacitively-coupled), the DC readout cannot be carried out. To electrically contact the 2DEG/2DHG channel underneath, about 5-20 nm bellow the metallisations, the AC-frequency regime must be used. In other words, the AC readout or impedance measurements of the electric current flowing through the 2DEG/2DHG-channel should be performed in this particular case. The capacitive coupling of the non-ohmic metal contacts with the 2DEG/2DHG channel becomes possible only if sufficiently high AC frequency, higher than 30 kHz, is applied to the metallisations. To sum up, the electrical metallisations, which are capacitively coupled to the 2DEG/2DHG channel utilise the known phenomenon of energy transfer by displacement currents. These displacement currents are induced by existing electrical fields between the electrical metallisations and the 2DEG/2DHG conducting channel operated in the AC frequency mode through the Schottky contact as explained above.

FIG. 2e schematically shows an expanded cross-sectional (XZ) view (A-A) of the exemplary bolometric or pyroelectric detector (16) of the PC-HEMT of the present embodiment. This exemplary detector (16) has a three-layer structure based on graphene layer (19) coated with a dielectric band-pass filter (20) and deposited on an alumina layer (18). This structure will be discussed below in detail. FIG. 2f schematically shows the top (XY) view and the basic topology of this PC-HEMT of the present invention, with the bolometric or pyroelectric detector (16).

The transistor of the present invention may further comprise a dielectric layer of 1-10 nm thickness. This dielectric layer may be deposited on top of the barrier layer (12). This configuration prevents strong electrical leakage at the metal/top layer interface. The dielectric layer used for the device passivation, may be made, for example, of SiO—SiN—SiO (“ONO”) stack of 100-100-100 nm thickness or SiN—SiO—SiN (“NON”) stack having the same thicknesses. It may be deposited on top of the barrier layer by a method of plasma-enhanced chemical vapour deposition (PECVD), which is a stress-free deposition technique.

Electrical metallisations (14) connect the transistor to the electric circuit and allow the electric current to flow between source and drain contact (15) areas via the two-dimensional electron gas (2DEG) or two-dimensional hole gas (2DHG) channel (13). Metallisations (14) may be made of metal stacks, such as Cr/Au, Ti/Au, Ti/W, Cr/Al and Ti/Al. The Cr or Ti layers of the metal stack is, for example, of 5-10 nm thickness, while the second metal layer, such as Au, W and Al, is of 100-400 nm thickness. Metallisations (14) may be chosen according to the established technology and assembly line at a particular clean room fabrication facility.

In some embodiments, substrate layer (10) may be composed, for example, of sapphire, silicon, silicon carbide, gallium nitride or aluminium nitride. The hetero-junction structure (11, 12) may be deposited on the substrate layer (10), for example, by a method of metalorganic chemical vapour deposition (MOCVD), thereby forming the pseudo-conducting 2DEG or 2DHG channel (13) in the close proximity to the interface between the buffer layer (11) and the barrier layer (12). The barrier layer (12) then may be either recessed or grown in the recessed open-gate area (17) as a very thin layer between the source and drain contact (15) areas.

The 2DEG or 2DHG conducting channel (13) formed near the interface between the buffer layer (11) and the barrier layer (12) serves as a main sensitive element of the transistor reacting to a surface charge and potential. The 2DEG or 2DHG channel (13) is configured to interact with very small variations in surface or proximal charge or changes of electrical field on the top layer/bolometric or pyroelectric layer gate interacting with the donor-like surface trap states of the barrier layer. This will be discussed below in detail.

The term “2DEG” mentioned in the present description and claims should not be understood or interpreted as being restricted to the two-dimensional electron gas. As stated above and will be explained later in this application, the two-dimensional hole gas may also be a possible current carrier in a specific heterojunction structure. Therefore, the term “2DEG” may be equally replaced with the term “2DHG” without reference to any particular PC-HEMT configuration.

In some embodiments, the PC-HEMT multilayer heterojunction structure of the embodiments is grown from any available III-V single-crystalline or polycrystalline semiconductor materials, such as GaN/AlGaN, GaN/AlN, GaN/InAlGaN, GaN/InAlN, GaN/InN, GaAs/AlGaAs, InN/InAlN or LaAlO₃/SrTiO₃. In a specific case of the hetero-junction structure grown from GaN/AlGaN, it has been experimentally found that the highest sensitivity of the sensor is achieved when thickness of the top recessed layer (GaN or AlGaN) in the open gate area between the source and drain contacts is 5-9 nm, preferably 6-7 nm, more preferably 6.2-6.4 nm. In addition, it was also found that the sensor exhibits its highest sensitivity when surface roughness of the top recessed layer is about 0.2 nm or less, preferably 0.1 nm or less, more preferably 0.05 nm.

Thus, the top layer recessed in the open gate area to 5-9 nm must be optimised for significantly enhancing sensitivity of the sensor. This specific thickness of the top layer was surprisingly found to correspond to the “pseudo-conducting” current range between normally-on and normally-off operation modes of the 2DEG channel and requires further explanation.

“Pseudo-conducting” current range of the 2DEG channel (to distinguish from normally-conducting) is defined as an operation resonance range of the channel between its normally-on and normally-off operation modes. “Trap states” are states in the band-gap of a semiconductor which trap a carrier until it recombines. “Surface states” are states caused by surface reconstruction of the local crystal due to surface tension caused by some crystal defects, dislocations, or the presence of impurities. Such surface reconstruction often creates “surface trap states” corresponding to a surface recombination velocity.

Classification of the surface trap states depends on the relative position of their energy level inside the band gap. The surface trap states with energy above the Fermi level are acceptor-like, attaining negative charge when occupied. However, the surface trap states with energy below the Fermi level are donor-like, positively charged when empty and neutral when occupied. These donor-like surface trap states are considered to be the source of electrons in the formation of the 2DEG channel. They may possess a wide distribution of ionization energies within the band gap and are caused by redox reactions, dangling bonds and vacancies in the surface layer. A balance always exists between the 2DEG channel density and the number of ionised surface donors which is governed by charge neutrality and continuity of the electric field at the interfaces.

Thus, the donor-like surface traps at the surface of the top layer are one of the most important sources of the 2DEG in the channel. However, this only applies for a specific top layer thickness. In a relatively thin top layer, the surface trap state is below the Fermi level. However, as the top layer thickness increases, the energy of the surface trap state approaches the Fermi energy until it coincides with it. The thickness of the top layer corresponding to such situation is defined as “critical”. At this point, electrons filling the surface trap state are pulled to the channel by the strong polarisation-induced electric field found in the top layer to form the 2DEG instantly.

If the surface trap states are completely depleted, further increase in the top layer thickness will not increase the 2DEG density. Actually, if the 2DEG channel layer fails to stretch the top layer, the later will simply relax. Upon relaxation of the top layer, many crystal defects are created at the interface between the top layer and the layer right underneath it, and the piezoelectric polarisation instantly disappears causing deterioration in the 2DEG density.

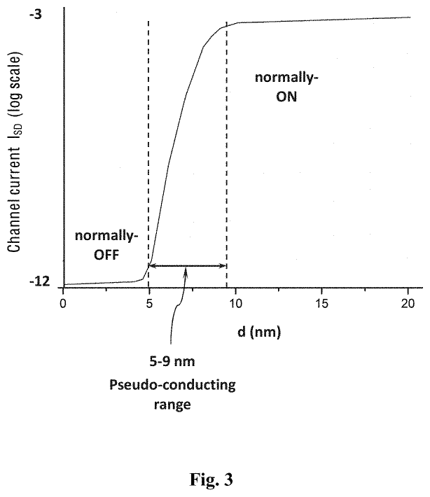

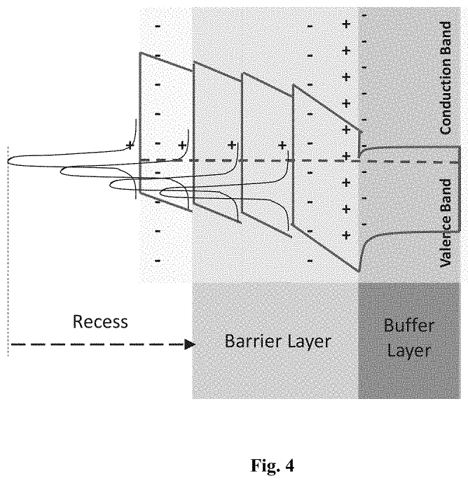

In order to illustrate the above phenomenon of the pseudo-conducting current, reference is now made to the following figures. FIG. 3 shows the dependence of the source-drain current (a charge carrier density) on the recessed AlGaN layer thickness. As seen from the plot, transistors that have a thickness of the top layer larger than 9 nm form normally-on 2DEG channels. In such transistors, due to the inherent polarisation effects present in the III-V materials, a thin sheet of charges is induced at the top and bottom of the interfaces of the top layer. As a result, a high electric field is induced in the top layer, and surface donor states at the top interface start donating electrons to form the 2DEG channel at the proximity of the hetero-junction interface without the application of a gate bias. These transistors therefore constitute normally-on devices. On the other hand, the transistors that have a thickness of the top layer lower than about 5 nm act constitute normally-off devices. Energy equilibrium between the donor surface trap states and AlGaN tunnel barrier leads to the 2DEG formation (charge neutrality combined with the lowest energy level) at the conduction band discontinuity. As explained above, decrease in the thickness of the AlGaN layer results in increase of the energy barrier. As a result, the ionisable donor-like surface trap states, which are responsible for electron tunneling from the surface to 2DEG, drift bellow the Fermi level, thereby minimizing the electron supply to the 2DEG channel. This theoretical situation is further illustrated in FIG. 4. Therefore, the recess of the AlGaN layer from 9 nm to 5 nm leads to huge drop in conductivity of the two-dimensional electron gas for six orders of magnitude.

In view of the above, it is clear that the mechanism of the 2DEG depletion based on recessing the top layer is strongly dependent on the donor-like surface trap states (or total surface charge). As the thickness of the top layer decreases, much less additional external charge is needed to apply to the top layer surface in order to deplete the conductive 2DEG channel. There is a critical (smallest) barrier thickness, when this channel is mostly depleted but still highly conductive due to a combination of the energy barrier and the donor surface trap states energy. At this critical thickness, even the smallest energy shift at the surface via any external influence, for example polarisation of the surface, leads immediately to the very strong 2DEG depletion. As a result, the surface of the top layer at this critical thickness is extremely sensitive to any smallest change in the electrical field of the surroundings. Thus, the recess of the top layer from 9 nm down to 5 nm significantly reduces the 2DEG density, brought the sensor of the invention to the “near threshold” operation and results in highly increased surface charge sensitivity. The specific 5-9 nm thickness of the top layer is actually responsible for the pseudo-conducting behaviour of the 2DEG channel and gives the sensor an incredible sensitivity.

The top layer is recessed to this specific thickness after subjecting to short plasma activation by an ultra-low damage reactive-ion etching technique using inductively-coupled plasma (ICP) with a narrow plasma-ion energy distribution. Such short plasma treatment allows much lower roughness of the surface, which is a function of the semiconductor vertical damage depth during the plasma etching process. Such low surface roughness (about 0.2 nm and less) can be achieved only via this ICP-RIE ultra low damage etching process with a narrow plasma-ion energy distribution, and this inherently results in a very low vertical damage depth to the top layer, which allows the minimal surface scattering and minimal surface states-2DEG channel interaction with the maximum signal-to-noise ratio of the sensor. Thus, the depth effect of the vertical sub-nanometre damage to the top recessed layer, due to an ultra-low damage ICP-RIE etching process with a very narrow plasma-ion energy distribution, is the only way to optimally achieve the required sub-nanometre roughness of the semiconductor surface. This inherently results in an adjustable pseudo-conductive working point with the highest charge sensitivity ever possible. This depth effect is always inherent to the sub-nanometre roughness of the semiconductor surface, measured using AFM (atomic force microscope).

In general, the term “surface roughness” as used in the present invention is well defined in the art. “Surface roughness” is a component of surface texture quantified by the deviations in the direction of the normal vector of a real surface from its ideal form. If these deviations are large, the surface is rough; if they are small, the surface is smooth. In surface metrology, surface roughness is typically considered to be the high-frequency, short-wavelength component of a measured surface. However, in practice it is often necessary to know both the amplitude and frequency to ensure that a surface is fit for a purpose. See more information on the surface roughness and its measurements, for example, in Wikipedia (https://en.wikipedia.org/wiki/Surface_roughness).

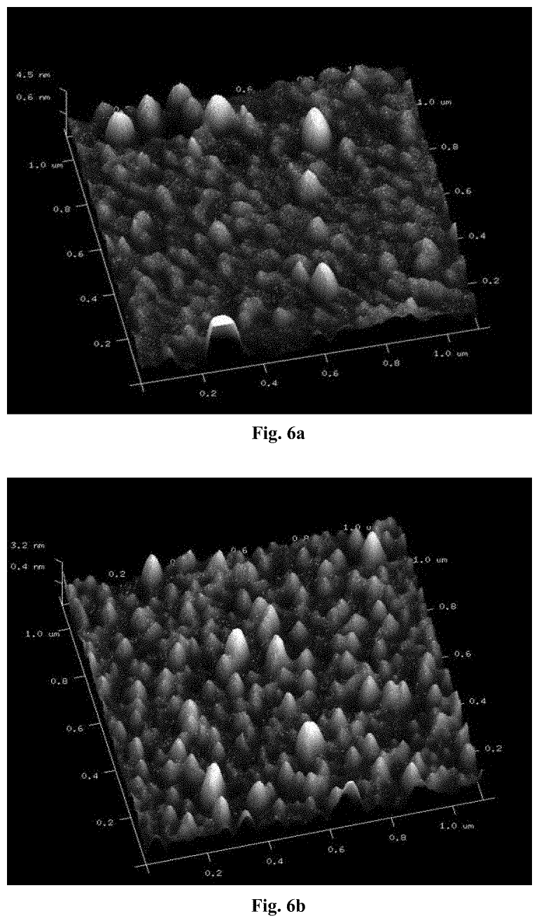

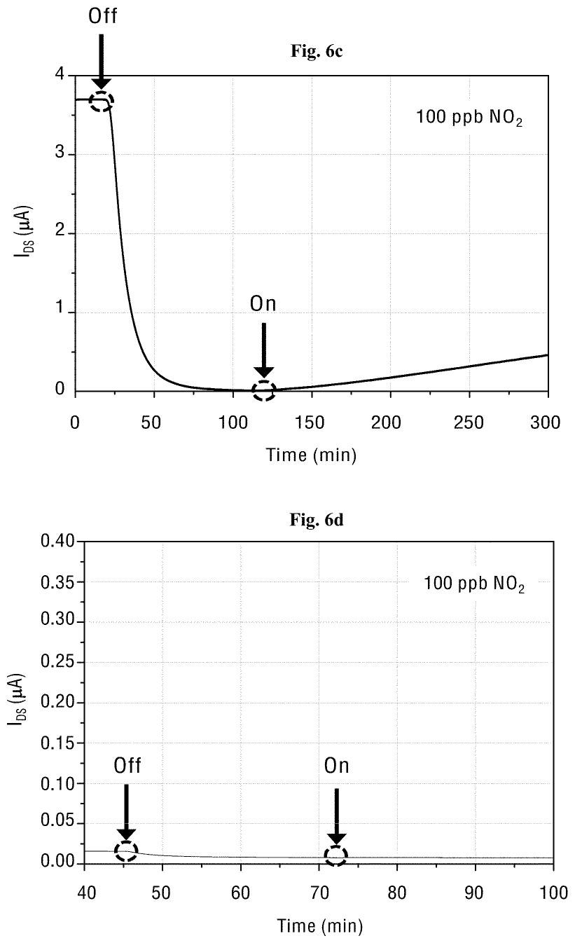

In the present invention, as mentioned above, surface roughness is measured using atomic force microscope (AFM), and the parameter that characterises the surface roughness is root-mean squared (RMS). For more information, see E. Paul Degarmo et al., 2003, “Materials and Processes in Manufacturing” (9^{th} Ed.), Wiley, page 223. See the example in FIGS. 6a and 6b below. The surface roughness of the top semiconductor layer (buffer or barrier) is measured before placing the bolometric or pyroelectric detector (16) on its top. As it will be described below, the surface roughness of the top semiconductor layer of the PC-HEMT structure strongly affects the coupling of the pyroelectric polarisation to the 2DEG/2DHG channel. In addition to its quantum effect, the low surface roughness actually allows a much better contact between the metamaterial layer (bolometric or pyroelectric) and the top semiconductor layer (buffer or barrier) and has a major contribution to the effectiveness of the polarisation coupling.

Thus, in addition to the recessed top layer thickness, roughness of the top layer surface is another very important parameter. It has been surprisingly found that the roughness of the top layer surface (in the open gate sensitive area) bellow 0.2 nm prevents scattering of the donor-like surface trap states. Thus, combination of these two features: 5-9 nm thickness of the top layer in the open gate area and strongly reduced roughness of its surface (bellow 0.2 nm) make the sensor incredibly sensitive.

To sum up, all known HEMT devices are classified nowadays in two types: normally-on and normally-off. The present invention discloses a third (phenomenal) type, pseudo-conducting, which can be described as both normally-on and normally-of at the same time. It is a resonance device operating based on a quantum superposition principle, hence its incredible sensitivity (switching between on and off takes no time). The amplification of electrical current observed in the pseudo-conducting transistor of the present invention under any small external effect is enormous. Every tiny electrical potential or piezoelectric impact, or a single molecule charge, even remotely (from the distance up to few meters) immediately destroys this quantum equilibrium and either closes the channel or opens it. This is the resonance effect that the present inventors observed unexpectedly when they were working on improving the surface flatness of the top layer. Upon recessing the top layer down to 5 nm, when removing atom layer by layer with short plasma pulses using their proprietary technique described below, thus maintaining the surface roughness at 0.2 nm and less, the inventors suddenly began seeing the unusually drastic increase of the signal. When the top layer was further recessed to 4 nm, this effect disappeared and the transistor returned its normal characteristics as a normally-off HEMT device.

Following this surprising experimentally observed phenomenon, the present inventors tested different ranges of thickness and roughness and arrived to the final result that this incredibly high amplification of the HEMT sensitivity occurs only in the range of 5-9 nm thickness of the top layer. However, in order to obtain and observe this phenomenal hypersensitivity effect of the transistor, the top layer surface should be flat with roughness 0.2 nm and less. If this roughness (flatness) is not maintained at 0.2 nm and less, the quantum effect cannot be created and observed.

Thus, notwithstanding the structural similarity, the PC-HEMTs of the present invention represent an entirely different type of the HEMT devices if compared to normally-on and normally-off HEMTs, operating according to different physical principles. The PC-HEMTs of the present invention have their 2DEG conducting channel operating simultaneously in both normally-on and normally-off states (resonance). Taking into account that the 2DEG channel is a quantum system, its behaviour in the PC-HEMTs of the present invention can be explained by a quantum superposition, i.e. a quantum system existing in several separate quantum states at the same time. Since the major characteristics of a transistor is how fast it is switched between “on” and “off” states, having such “quantum” transistor means it takes virtually no time to switch between those two states, hence the highest sensitivity ever possible.

In a certain aspect, the method for manufacturing of the PC-HEMTs of the present invention comprises the following steps:
Step 1: Plasma-enhanced atomic layer deposition (ALD) of alumina (Al₂O₃) on a pre-aligned masked Si—GaN/AlGaN wafer with nitrogen-plasma de-trapping for the thickness of the Al₂O₃ layer being 3-10 nm. The Al₂O₃ layer thickness was measured with an X-ray reflectometer.
Step 2: Plasma-enhanced atomic layer deposition (ALD) pattering of the wafer coated with the thin Al₂O₃ layer in Step 1, with hydrogen fluoride (HF) or using the aforementioned reactive-ion etching (RIE) technique.
Step 3: Optionally creating the source and drain ohmic contacts (in case ohmic contacts are required) on the coated wafer obtained in Step 2 from metal stacks, for example Ti/Al/Mo/Au, Ti/Al/Ni/Au, Ti/Au and Ti/W, having 15-50 nm thickness, using spin-coating technique or e-beam physical vapour deposition (VPD) of the stack metals. The deposition rates using the e-VPD technique were determined for the ohmic-stack metals using the Dektak Profilometer with dummy lift-off samples.
Step 4: Two-dimensional electron gas (2DEG) channel-pattering of the wafer obtained in Step 3 with argon- or nitrogen-ion implantation.
Step 5: Plasma-enhanced chemical vapour deposition (CVD) of the ONO stack over the wafer obtained in Step 4. This is the stress-free technique to deposit the layer of the SiO—SiN—SiO stack having an exemplary thickness of about 200-300 nm and structured by the ICP-RIE dry etching, which is the CF4-based etching method. In this step, the pseudo-conducting channel areas and ohmic electrical contact pads of the transistor become available.
Step 6: Optional lift-off deposition of an Au or Ti/W-CMOS-gate electrode (in case a gate electrode is to be deposited on the top layer of the heterojunction structure for an integrated MMIC-HEMT-based amplifier manufacturing).
Step 7: Optional plasma-enhanced ALD pattering with RIE or HF above sensing area (in case the plasma-enhanced ALD layer deposited in Step 1 is removed separately to ONO stack).
Step 8: Atomic layer etching (ALE) of the wafer obtained in Steps 5-7. This sophisticated technique carried out in the clean manufacturing cluster of the applicant is the only technique allowing the removal of individual atomic layers (the top atomic layers of the wafer). ALE is a way better-controlled technique than RIE, though it has not been commercially used until now because very sophisticated gas handling is required, and removal rates of one atomic layer per second are the real state of the art. This step is the step of creating the pseudo-conducting working point of the transistor, because ALE allows achieving the specific thickness of 5-9 nm thickness of the top layer in the open gate area with the extremely low surface roughness of the top layer below 0.2 nm.
Step 9: Optional plasma-enhanced CVD or ALD of the dielectric layer used for device passivation and in some gas sensors.
Step 10: Optional deep reactive-ion etching (DRIE or Bosch process) of the Si-substrate under sensing areas (in case the substrate is on the free-standing membranes—used, for example, in RF-HEMTs, FBAR and SAW sensors).

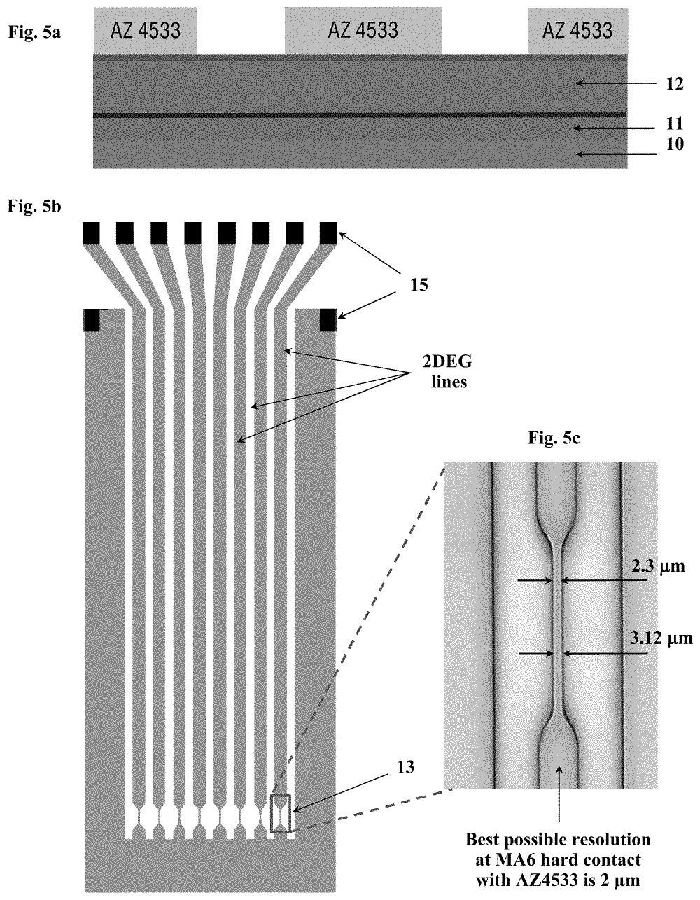

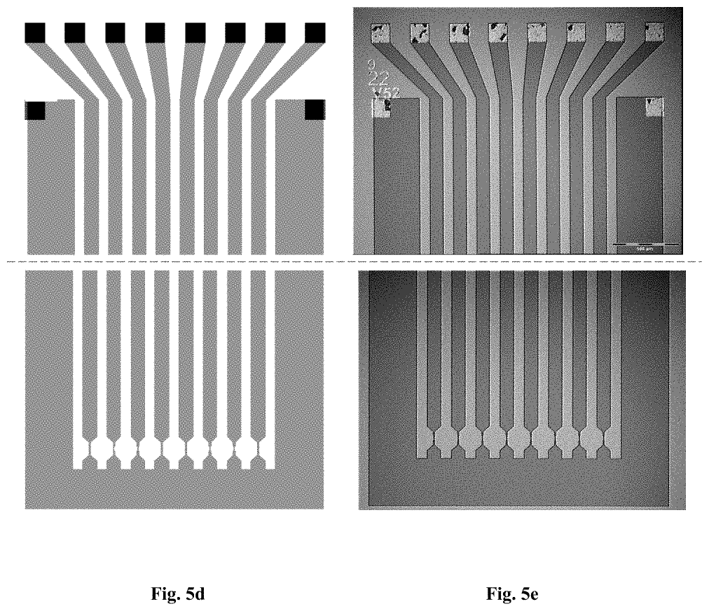

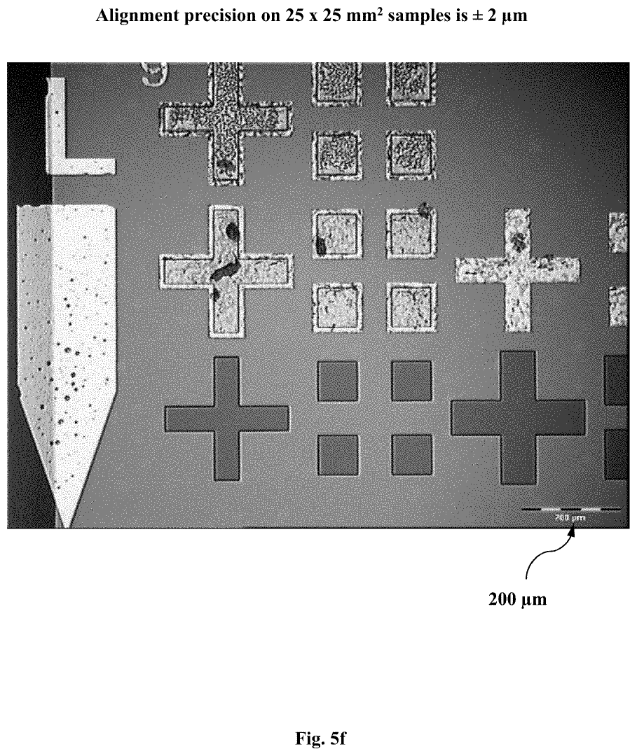

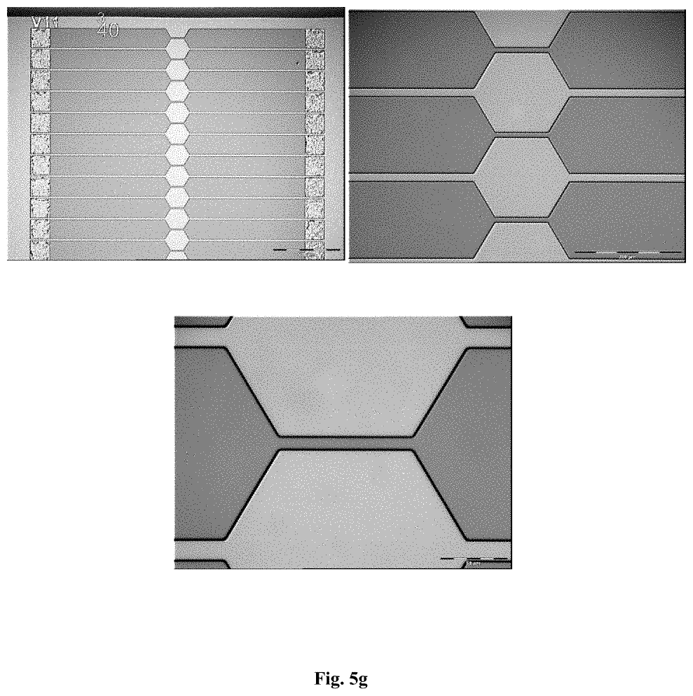

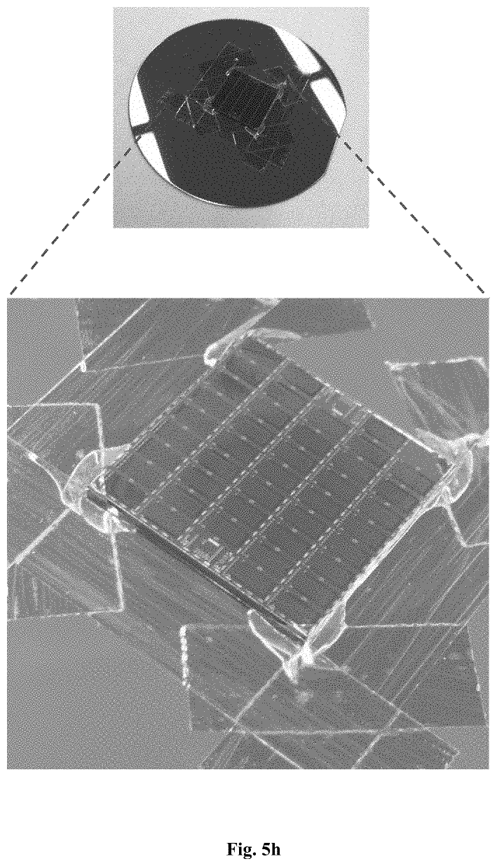

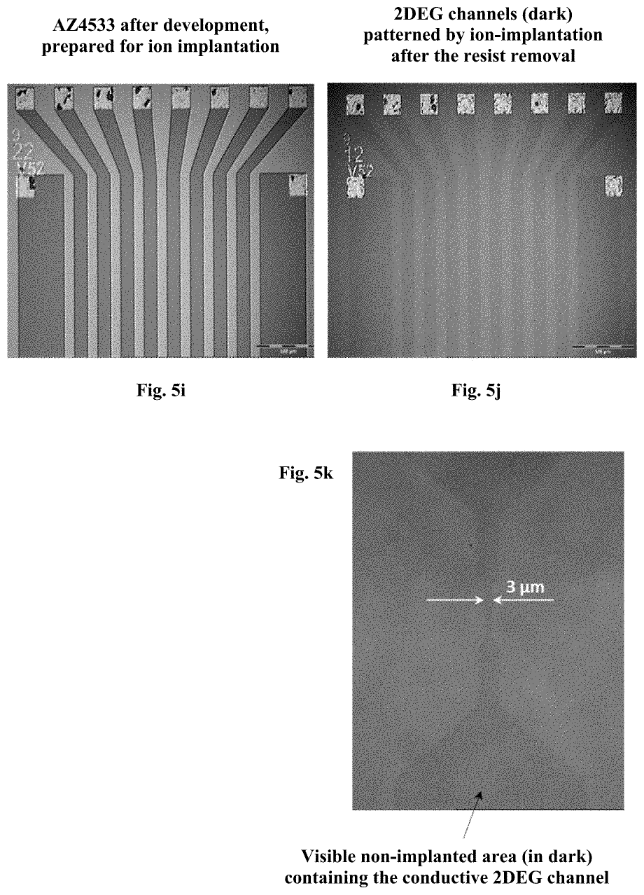

Reference is now made to FIGS. 5a-5c showing the sensor, which is obtained in Step 4 of the 2DEG-channel pattering. The lithography of the sensor was performed with AZ 4533, which is a positive thick resist having optimised adhesion for common wet etching. The lithographic resist film thickness obtained at 7000-rpm spin speed and at 100° C. for 1 min was 3 μm. Thus, as seen in the lithographic image of FIG. 5c, the formed 2DEG channel (13) is approximately 2-3 μm wide. The overall exposure time was 9 sec, followed by 5-min development in MIF726 developer.

FIG. 5d-5e show the mask and corresponding lithographic image, respectively, of the sensor layout of the present invention. FIG. 5f demonstrates the high alignment precision of ±2-μm on 25×25 mm² samples in the lithography of the sensor layout of the present invention. FIG. 5g shows the lithographic images of the multichannel samples. FIG. 5h shows the fixed sensor chip sample on the Si—GaN/AlGaN wafer, which contains approximately 30-32 sensors with 4-8 channels on each sample and prepared for ion implantation. FIG. 5i shows the obtained lithographic image of the present sensor layout with the AZ4533 resist after development, prepared for ion implantation. FIG. 5j shows the 2DEG channels (dark) patterned by ion-implantation after the resist removal. The argon-ion implantation was conducted with 20 keV and 30 keV energies and with an exemplary dose of 2.5e¹³/cm² and a 7° tilt angle. AZ4533 was removed with oxygen plasma at 220 W for 10 min. FIG. 5k shows the visible non-implanted area containing the conductive 2DEG channel.

The atomic layer etching (ALE) performed in Step 8 of the manufacturing process is the most important stage in the process. As mentioned above, it allows the controlled recess of a top layer, removing a single atomic layer-by-layer, where the etch thickness is in the order of magnitude of a single atomic monolayer. As explained above, such ultra-low damage to the top layer of the heterogeneous structure, when the actual surface roughness is controlled by a single atomic monolayer, allows to achieve the sub-nanometre roughness (about 0.2 nm and less) of the top layer when its thickness is only few nanometres (5-9 nm).

The ALE process sequence consists of repeated cycling of process conditions. The total amount of material removed is determined by the number of repeated cycles. Each cycle is typically comprised of four steps: adsorption, first purge, desorption and second purge. During the adsorption step of the cycle, reactive species are generated in the reactor (for example, upon plasma excitation), adsorbed by, and react with material on the wafer. Due to the self-limiting process, and with the proper choice of reactants and process conditions, reaction takes place with only a thin layer of material, and the reaction by-products are formed. This step is followed by purging of the reactor to remove all traces of the reactant. Then the by-product desorption takes place due to bombardment of the wafer surface by noble gas ions with a tightly controlled energy. Again, by-products are purged from the reactor, and the wafer is ready for the last two (optional) steps of the manufacturing process.

Reference is now made to FIG. 6a showing an exemplary AFM image of the top recessed layer surface of the PC-HEMT produced by the manufacturing process of the present invention. The measured RMS value of the surface roughness is 0.674 nm in this example. For comparison, FIG. 6b shows the AFM surface image of the top recessed layer of the HEMT made by a conventional manufacturing process. In this conventional process, the HEMT initially had a top ultrathin-grown AlGaN layer of the 6-7 nm thickness. This layer was recessed with inductively-coupled plasma (ICP) for 60 sec using a conventional reactive-ion etching (RIE) technique. The measured RMS value of the surface roughness is 1.211 nm in this case, which is almost twice higher than the surface roughness seen in FIG. 6a for the PC-HEMT manufactured by the process of the present invention.

FIG. 6c show the time-dependent plot of the drain-source electric current I_{DS} of the nitrogen oxide sensor, which measures 100 ppb of the NO₂ gas in 80%-humid air, where the sensor incorporates the PC-HEMT made by the manufacturing process of the present invention. Further, for comparison, FIG. 6d show the time-dependent plot of the I_{DS} of the nitrogen oxide sensor measuring 100 ppb of the NO₂ gas in 80%-humid air, where the sensor incorporates and based on the HEMT made by the conventional manufacturing process. It is clear from these comparative examples that the manufacturing process of the present invention based on the ultra-low damaging RIE with a narrow plasma-ion energy distribution leads to much lower roughness of the semiconductor surface, which in turn leads to incredibly high sensitivity of the sensor.

It should be understood that the above comparative example demonstrating the surface roughness of 0.674 nm for the PC-HEMT is not limiting to this particular roughness in any sense. It is shown here only for comparison with the conventional HEMT manufacturing technology, which under the same conditions produces much rougher semiconductor surfaces. However, it is clear that the above-described method for manufacturing the PC-HEMT of the present invention does indeed provide a surface roughness of 0.2 nm or less.

In a further aspect, the hetero-junction structure may be a three-layer structure consisting of two GaN layers and one AlGaN layer squeezed between said GaN layers like in a sandwich, wherein the top layer is a buffer layer. This may lead to formation of the two-dimensional hole gas (2DHG) in the top GaN layer above the AlGaN layer which results in reversing polarity of the transistor compared to the two-layer structure discussed above.

In general, polarity of III-V nitride semiconductor materials strongly affects performance of the transistors based on these semiconductors. Quality of the wurtzite GaN materials can be varied by their polarity, because both the incorporation of impurities and the formation of defects are related to the growth mechanism, which in turn depends on surface polarity. The occurrence of the 2DEG/2DHG and the optical properties of the hetero-junction structures of nitride-based materials are influenced by the internal field effects caused by spontaneous and piezoelectric polarisations. Devices in all of the III-V nitride materials are fabricated on polar {0001} surfaces. Consequently, their characteristics depend on whether the GaN layers exhibit Ga-face positive polarity or N-face negative polarity. In other words, as a result of the wurtzite GaN materials polarity, any GaN layer has two surfaces with different polarities, a Ga-polar surface and an N-polar surface. A Ga-polar surface is defined herein as a surface terminating on a layer of Ga atoms, each of which has one unoccupied bond normal to the surface. Each surface Ga atom is bonded to three N atoms in the direction away from the surface. In contrast, an N-polar surface is defined as a surface terminating on a layer of N atoms, each of which has one unoccupied bond normal to the surface. Each surface N atom is also bonded to three Ga atoms in the direction away from the surface. Thus, the N-face polarity structures have the reverse polarity to the Ga-face polarity structures.

As described above for the two-layer heterojunction structure, the barrier layer is always placed on top of the buffer layer. Dependent on the structure polarity, the layer which is recessed in the two-layer heterojunction structure can be AlGaN layer. As a result, since the 2DEG is used as the conducting channel and this conducting channel is located slightly below the barrier layer (in a thicker region of the GaN buffer layer), the hetero-junction structure is grown along the {0001}-direction or, in other words, with the Ga-face polarity. However, as explained above, the physical mechanism that leads to the formation of the 2DEG channel is actually a polarisation discontinuity at the AlGaN/GaN interface, reflected by the formation of the polarisation-induced fixed interface charges that attract free carriers to form a two-dimensional carrier gas. It is a positive polarisation charge at the AlGaN/GaN interface that attracts electrons to form 2DEG in the GaN layer slightly below this interface.

As noted above, polarity of the interface charges entirely depends on the crystal lattice orientation of the hetero-junction structure, i.e. Ga-face versus N-face polarity, and the position of the respective AlGaN/GaN interface in the hetero-junction structure (above or below the interface). Therefore, different types of the accumulated carriers can be present in the hetero-junction structure of the embodiments.

In case of the three-layer hetero-junction structure, there are four possible configurations:

### Ga-Face Polarity

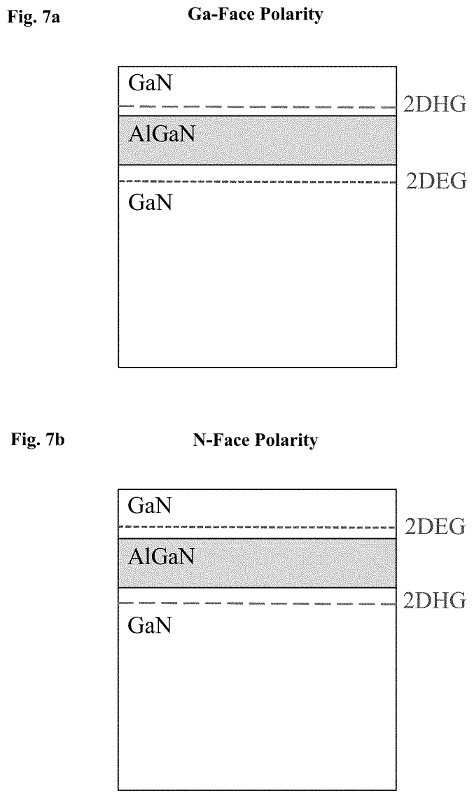

1) The Ga-face polarity is characterised by the 2DEG formation in the GaN layer below the AlGaN barrier layer. This is actually the same two-layer configuration as described above, but with addition of the top GaN layer. In this configuration, the AlGaN barrier layer and two GaN layers must be nominally undoped or n-type doped.
2) In another Ga-face configuration shown in FIG. 7a, in order to form the conducting channel comprising a two-dimensional hole gas (2DHG) in the top GaN layer above the AlGaN barrier layer in the configuration, the AlGaN barrier layer should be p-type doped (for example, with Mg or Be as an acceptor) and the GaN buffer layer should be also p-type doped with Mg, Be or intrinsic.

### N-Face Polarity

3) The N-face polarity is characterised by the 2DEG formation in the top GaN layer above the AlGaN barrier layer, as shown in FIG. 7b. In this case, the AlGaN barrier layer and two GaN layers must be nominally undoped or n-type doped.
4) The last configuration assumes that the 2DHG conducting channel is formed in the buffer GaN layer below the AlGaN barrier layer. The top GaN layer may be present (three-layer structure) or not (two-layer structure) in this case. The AlGaN barrier layer must be p-type doped (for example, with Mg or Be as an acceptor) and the bottom GaN layer should be also p-type doped with Mg, Be or intrinsic.

Thus, there are four hetero-junction three-layer structures implemented in the transistor of the embodiments, based on the above configurations:
A. Ga-Face GaN/AlGaN/GaN heterostructure with the 2DEG formed in the GaN buffer layer below the AlGaN barrier layer. In this case, the top GaN layer may be omitted to obtain the two-layer structure. For the three-layer structure, the top GaN layer must be recessed to 1-9 nm thickness in the open gate area or grown with this low thickness, with the roughness below 0.2 nm, and the thickness of the AlGaN barrier can be adjusted properly during growth
B. Ga-Face GaN/AlGaN/GaN heterostructure with the 2DHG conducting channel formed in the top GaN layer above the AlGaN barrier layer. The top GaN layer must be recessed to 5-9 nm thickness in the open gate area with the roughness below 0.2 nm, and the thickness of the AlGaN barrier layer can be adjusted properly. P-type doping concentrations of the GaN layer and AlGaN barrier have to be adjusted; the 2DHG has to be contacted (in the ideal case by ohmic contacts).
C. N-Face GaN/AlGaN/GaN heterostructure with the 2DEG in the top GaN layer above the AlGaN barrier layer. The top GaN layer must be recessed to 5-9 nm thickness in the open gate area with the roughness below 0.2 nm. Thickness of the AlGaN barrier can be adjusted during growth. N-type doping levels of the GaN buffer layer and the AlGaN barrier layer must be adjusted; the 2DEG has to be contacted (in the ideal case by ohmic contacts).
D. N-Face GaN/AlGaN/GaN heterostructure with the 2DHG in the GaN buffer layer below the AlGaN barrier layer. In this case, the top GaN layer may be omitted to obtain the two-layer structure. In both, the two-layer and three-layer configurations, the top GaN layer must be recessed to 1-9 nm thickness in the open gate area with the roughness below 0.2 nm, and the thickness of the AlGaN barrier can be adjusted properly.

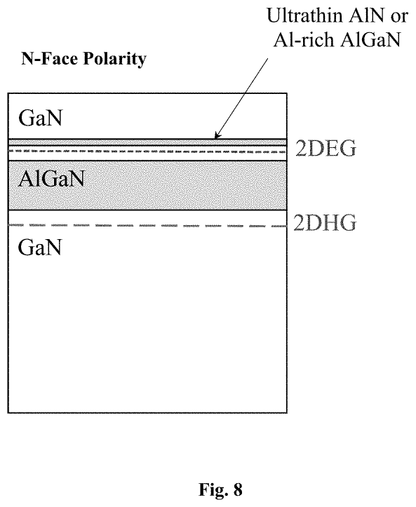

In all the above structures, the deposition of a dielectric layer on top might be beneficial or even necessary to obtain a better confinement (as in case of the N-face structures). As shown in FIG. 8, for the above “C” structure, it may be even more beneficial to include an ultrathin (about 1 nm) AlN or AlGaN barrier layer with high Al-content on top of the 2DEG channel to improve the confinement.

The preferable structures of the embodiments are structures “B”, “C” and “D”. In the structure “B”, the 2DHG conducting channel formed in the top GaN layer, which has a higher chemical stability (particularly towards surface oxidation) than the AlGaN layer. Concerning the structure “C”, the 2DEG conducting channel might be closer to the surface. Therefore, the electron mobility might be lower than in the 2DEG structure with the Ga-face polarity. In general, the polarity of the heterostructure can be adjusted by the choice of the substrate (e.g. C-face SiC) or by the growth conditions.

Thus, in a particular embodiment, the PC-HEMT of the present invention comprises the multilayer hetero-junction structure having one of the following structures:
A. (i) one top AlGaN layer recessed in an open gate area of the transistor to the thickness of 5-9 nm and having the surface roughness of 0.2 nm or less, and (ii) one bottom GaN buffer layer; said layers have Ga-face polarity, thus forming the two-dimensional electron gas (2DEG) conducting channel in said GaN layer, close to the interface with said AlGaN layer; or
B. (i) one top GaN layer recessed in an open gate area of the transistor to the thickness of 5-9 nm and having the surface roughness of 0.2 nm or less, (ii) one bottom GaN buffer layer, and (iii) one AlGaN barrier layer in between; said layers have Ga-face polarity, thus forming a two-dimensional hole gas (2DHG) conducting channel in the top GaN layer, close to the interface with said AlGaN barrier layer; or
C. (i) one top GaN layer recessed in an open gate area of the transistor to the thickness of 5-9 nm and having the surface roughness of 0.2 nm or less, (ii) one bottom GaN buffer layer, and (iii) one AlGaN barrier layer in between; said layers have N-face polarity, thus forming a two-dimensional electron gas (2DEG) conducting channel in the top GaN layer, close to the interface with said AlGaN barrier layer; or
D. (i) one top AlGaN layer recessed in an open gate area of the transistor to the thickness of 5-9 nm and having the surface roughness of 0.2 nm or less, and (ii) one bottom GaN buffer layer; said layers have N-face polarity, thus forming a two-dimensional hole gas (2DHG) conducting channel in the GaN buffer layer, close to the interface with said AlGaN barrier layer.

Terahertz radiation can penetrate thin layers of materials but is blocked by thicker objects. It falls in between infrared radiation and microwave radiation in the electromagnetic spectrum, and it shares some properties with each of these. Abundance of free electrons is required inside the semiconductor so that they can respond with the incoming frequency of the EM waves in the THz range. The fluctuation in carrier density can eventually be captured by an amplifier. Different approaches to THz detection have been recorded in literature till date. Most popular methods use a bolometric or pyroelectric insulator in HEMT detectors.

### Bolometric Detectors

One of the methods for detection of the sub-THz and THz signals utilizes bolometric or pyroelectric detectors in a HEMT device. A bolometer measures the changes in the heat input from the surroundings and converts this input into a measurable quantity such as a voltage or current. A bolometer therefore typically consists of an absorber and a thermometer, resulting in the increase in temperature due to absorption of infra-red (IR) radiation that ultimately causes a change in resistance of bolometer elements. The resistance change information is electrically transferred to the read-out integrated circuit (ROIC) for further processing. To obtain high sensitivity the thermometer is kept thermally insulated with the ROIC substrate.

Bhan et al in “Uncooled Infrared Microbolometer Arrays and their Characterisation Techniques (Review Paper)”, Defence Science Journal, 2009, 59(6), 580-589, described a typical microbolometer detector, which is shown in FIG. 9 (courtesy of the authors). The recent advances in microelectromechanical systems (MEMS) technology allow fabricating sensitive thermal bolometric detectors on thermally isolated hanging membranes. The bolometer employs a characteristic of thermally sensitive layer that changes its sheet resistance according to the change of the temperature (the larger the resistance change, the higher the temperature coefficient of resistance (TCR), hence, higher sensitivity). Many materials have been used for IR active layer of bolometer such as noble metals (Au, Pt, Ti, etc.) and semiconductors, such vanadium oxides, amorphous silicon, etc. The main thrust is to develop a technology that provides ultra-low-cost thermal IR imagers.

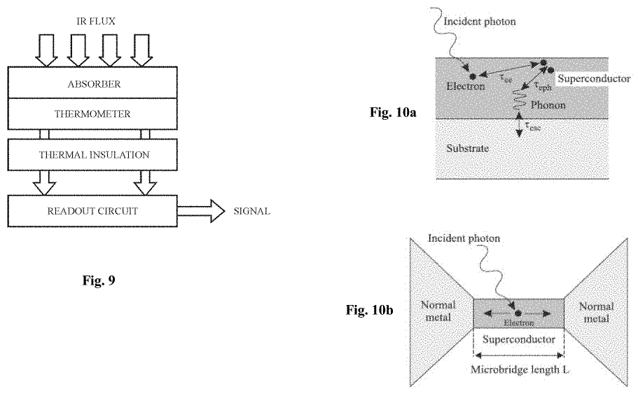

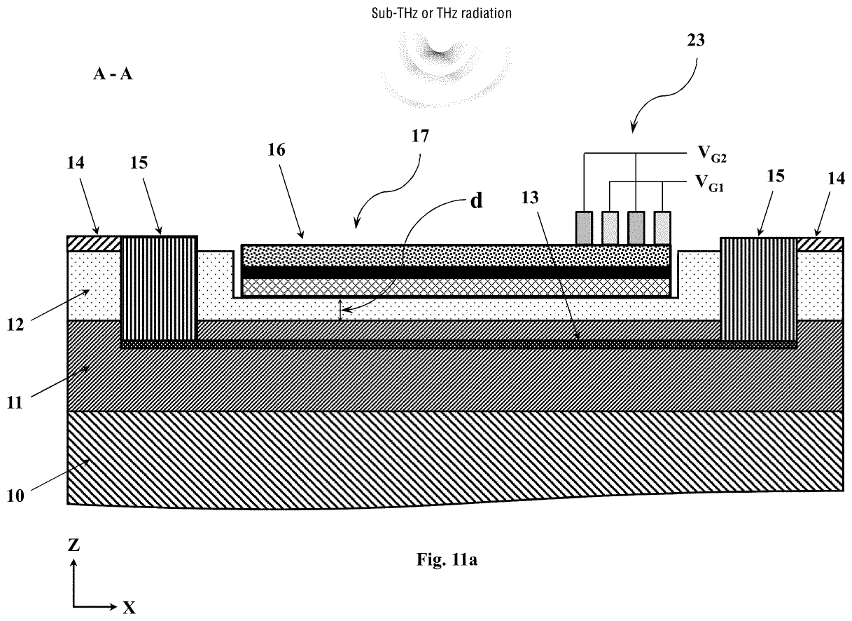

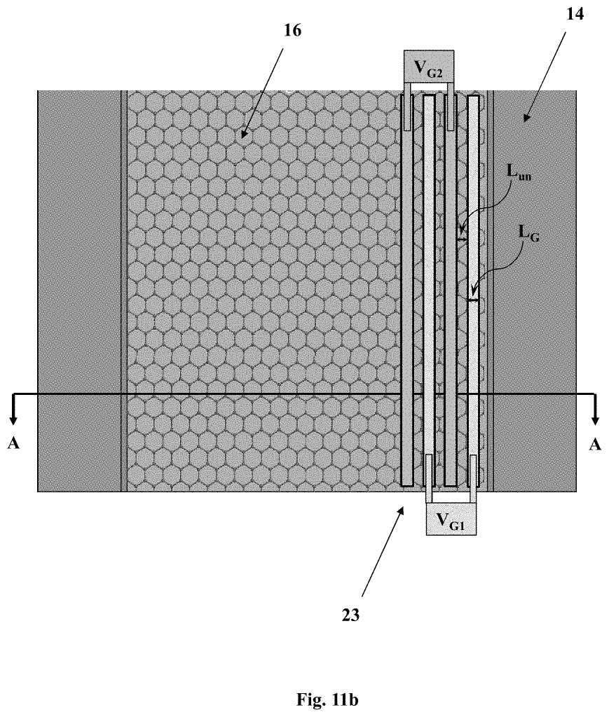

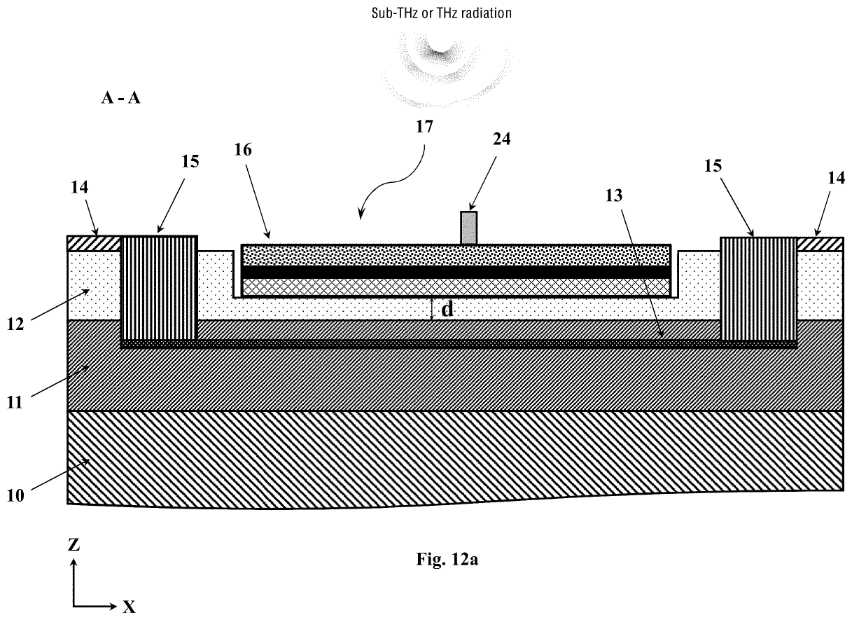

There are different methods of bolometric detection: regular bolometers, HEBs (hot electron bolometers) and TESs (transmission edge sensors). In principle, HEBs are quite similar to TESs, where small temperature changes, caused by the absorption of incident radiation, strongly influence resistance of a biased sensor near its superconducting transition. The main difference between HEBs and regular bolometers is how fast their response is. Rogalski and Sizov, “Terahertz detectors and focal plane arrays”, Opto-Electronics Review, 2011, 19, 346-404, described different types of HEBs, as shown in FIGS. 10a and 10b (courtesy of the authors).

Fast response time is achieved by allowing radiation power to be directly absorbed by electrons in the superconductor layer, rather than using a separate radiation absorber and allowing the energy to flow to the superconducting TES via phonons, as ordinary bolometers do. After photon absorption, a single electron initially receives an energy flux (hv), which is rapidly shared with other electrons, producing a slight increase in the excited electron temperature. In the next step, the excited electron subsequently relaxes to the bath temperature through emission of phonons, thereby heating the substrate. This phenomenon is called a “phonon cooled HEB” (FIG. 10a).

Another HEB method is a “diffusion cooled HEB”. In this method, hot electrons transfer their energy by diffusion to normal metals that form the electrical contact to external detector readout circuit and/or arms of a planar antenna as shown in FIG. 10b.

Any change in the temperature coefficient of resistance (TCR) would naturally affect the electrons or holes current in the 2DEG/2DHG channel. For example, Mitin et al in “Hot-electron micro and nanobolometers based on low-mobility 2DEG for high resolution THz spectroscopy”, Journal of Physics: Conference Series, 2014, 486, 012028, describes a device based on the concept that the THz electric field is induced in a gap between antenna apexes penetrated into a 2DEG layer and heated the electron gas in the channel. Ramaswamy et al in “2DEG GaN hot electron micro-bolometers and quantum cascade lasers for THz heterodyne sensing”, Proceedings SPIE Defence, Security, and Sensing, 2011, 8031, Micro- and Nanotechnology Sensors, Systems, and Applications III, 80310H, describes design, fabrication, and characterization of hot-electron bolometers placed over low-mobility 2DEG channel in AlInN/GaN and AlGaN/GaN heterostructures. A low contact resistance achieved in those devices ensures that the THz voltage primarily drops across the active region. Substantial responsivity and relatively small noise is achieved due to small heat capacity of electrons in low-dimensional semiconductor structures. Several design of devices were investigated, a floating gate and without gate. The floating gate device has higher responsivity than the devices without gate. One of the explanations could be that the gate electrode creates some depletion region under it, introducing a potential barrier to the current flowing in the channel. The THz radiation obtains polarisation parallel to direction of the bias current and perpendicular to the ohmic or non-ohmic contacts. This explains the observed strong preference of the response to the linear polarized terahertz field, which is perpendicular to the slit formed by the contact metallisations.

Graphene proved to be an excellent metamaterial in bolometric detectors. A single atomic layer of carbon atoms in graphene has an excellent HEB property. Broadband absorption of photons ranges from far infrared to ultraviolet. Graphene also features highest specific interaction strength (absorption per atom). For example, Fatimy et al in “Room temperature Terahertz hot electron bolometric detector based on AlGaAs/GaAs two dimensional electron gas”, 35th International Conference on Infrared, Millimeter, and Terahertz Waves, Rome, 2010, pp. 1-1, demonstrated the use of a bilayer graphene, which has a tunable bandgap, induces a perpendicular electric field (accomplished through gates above and below the graphene) giving rise to strongly electron-temperature dependent resistance at low temperatures and thereby making the device suitable for thermometry.

Carbon nanotubes (CNTs) is another metamaterial suitable for use in the bolometric detector (16) of the invention. It has an extraordinary ability to absorb electromagnetic waves in an ultra-wide spectral range, through both intra-band (free carrier) absorption and inter-band (excitonic) absorption processes. Kawano et al in “Terahertz sensing with a carbon nanotube/two-dimensional electron gas hybrid transistor”, Applied Physics Letters, 2009, 95, 083123, describes a carbon nanotube single-electron transistor (SET) integrated with a GaAs/AlGaAs heterostructure chip having a two-dimensional electron gas (2DEG) channel. In this hybrid structure, the absorption of THz radiation occurs in the 2DEG channel, but signal readout is carried out in the CNT-SET. The operation principle of this device is that the CNT-SET senses electrical polarisation induced by terahertz-excited electron-hole pairs in the 2DEG channel. The CNT-SET has the source drain electrodes with an interval of about 600 nm and the side-gate electrode operating at 2.5 K. The noise equivalent power of this detector is estimated to be 10⁻¹⁸-10⁻¹⁹ W/Hz^{1/2}.

### Pyroelectric Detectors

Pyroelectric detector is one of the most widely-used thermal infrared detectors, in which infrared radiation (IR) is transformed into an electrical signal. In pyroelectric detectors, via a window or IR filter with a transmission rate of τ_{F}, the radiation arrives at a pyroelectric element. The radiation flux Φ_{S} is absorbed and causes a change in temperature (ΔT_{P}) in the pyroelectric element. The thermal to electrical conversion is due to the pyroelectric effect by which the temperature change (ΔT_{P}) alters the charge density on the electrodes. An electrical conversion often follows in which, for example, an electrical signal is created by a preamplifier or impedance converter.

The basic fundamental principle behind any pyroelectric detector is to induce a net change in polarisation due to the incumbent radiation. Modern pyroelectric detectors cover the entire sub-THz and THz spectrum range with the best precision across the entire wavelength range and relative measurements from 30 THz to 0.1 THz. They can operate at room temperature operation, easier to use and inexpensive. Any change in polarisation would naturally affect the electron or hole current in the 2DEG/2DHG channel.

As with the above bolometric detectors, the exemplary material used for the pyroelectric detectors in the present invention is graphene. Graphene is a zero-gap semiconductor, because its conduction and valence bands meet at the Dirac points. Graphene has several amazing properties, such as very high electron mobility (more than 5000 cm²v⁻¹s⁻¹), tunable Dirac point via gate voltage, which increases the carrier concentration whenever required, and tunable resistance. Graphene is suitable for effective use with grating gates (slit gates with the slit width, which is small enough to resonate with THz radiation), and for use as a mono or bi-layer honeycomb over the gate dielectric to act as effective polarizer (the high mobility of electrons in graphene assists in quick polarisation due to incumbent THz radiation, which is then effectively coupled to the dielectric). Graphene can be used as a grating gate or antenna integrated gate in order to narrow down the tuning frequency of the detector to THz regime. All these properties of graphene makes it an excellent material for the pyroelectric detectors in the transistors of the present invention.

Another material used in the pyroelectric detectors of the present invention is carbon nano tubes (CNTs). Unlike graphene, which is a two-dimensional semi-metal, carbon nanotubes are either metallic or semiconducting along the tubular axis. Because of its nanoscale cross-section, electrons propagate only along the tube's axis. As a result, carbon nanotubes are frequently referred to as one-dimensional conductors. The maximum electrical conductance of a single-walled carbon nanotube is 2G₀, where G₀=2e²/h is the conductance of a single ballistic quantum channel. In addition, CNTs can have structural defects and impurities which may induce photon scattering and resistance. Tunable resistance feature of CNTs have made them a good candidate for bolometric and pyroelectric detectors.

LiTaO₃/BaTiO₃ pyroelectric detectors is another type of detectors used in the transistors of the present invention. Wang et al in “Preparation of room temperature terahertz detector with lithium tantalate crystal and thin film”, AIP Advances 2014, 4(2), 027106, reported that LiTaO₃ had been recorded as the pyroelectric material with least loss factor, which makes it a good candidate for the pyroelectric detector of the present invention.

### Metamaterials for Bolometric and Pyroelectric Detectors

In some embodiments, the bolometric or pyroelectric detector (16) of the present invention is composed of metamaterials such as graphene, carbon nanotubes, graphene/gold or copper/single layer graphene/copper composite, thereby creating metasurfaces, which are designed to modulate (allow or inhibit) propagation of electromagnetic waves in desired directions.

In general, “metamaterial” is an arrangement of artificial structural elements designed to achieve advantageous and unusual properties unattainable in natural media. A metamaterial gains its properties from its unique structure rather than composition. Metamaterials are generally engineered periodic or non-periodic material composites with sub-wavelength structures. They are employed to sense molecular vibrational fingerprints in the sub-THz, THz to mid-IR wavelengths. Their physical properties, such as the dielectric constant, permeability, and conductivity, can be arbitrarily designed by changing the structure and size of the periodic lattice.

### Theoretical and Experimental Studies

The PC-HEMT of the present invention is based on polarisation effects. The prototype device having AlGaN/GaN heterojunction structure was grown on Si substrates, to make the devices much more cost effective than with silicon carbide or sapphire substrate. The detector (16) of the prototype device comprises monolayer graphene packed in a honeycomb lattice as schematically shown in FIG. 2f. Such configuration offers efficient platform for strong light-matter interaction, due to its intrinsic high mobility and chiral electronic spectrum. From the first large-scale patterning of graphene-based detectors, performance has improved at a rapid pace.

Graphene, synthesized by various techniques including exfoliation of highly ordered pyrolytic graphite, chemical vapour deposition, and epitaxial growth on silicon carbide, exhibits prominent advantage for high frequency applications. Recent progress on either back-gated or top-gated graphene detectors integrated with high-k dielectric such as Al₂O₃, has achieved mobility over 8000 cm²/Vs at high charge density and 40000 cm²/Vs at low charge density, making graphene the most promising candidate for sub-THz and THz nanoelectronics. In principle, the free carrier density in graphene can be tuned by several orders of magnitude (10¹¹˜10¹⁴ cm⁻²).

Graphene also features Drude absorption by carriers which eventually determines the gain at a particular frequency. This resultant gain is the real part of the net dynamic conductivity. Such unique property allows strongly controlling the plasma waves from far-IR to THz frequencies. Use of monolayer graphene ensures, a huge availability of free charge carriers beneath the gate electrode. High mobility of graphene ensures effective polarisation of carbon atoms due to the incumbent THz radiation. Graphene monolayer acts as THz amplifier by simulated emission. Hence the effective use of graphene monolayer beneath the gate electrode would definitely increase the sub-THz and THz responsivity of the detector.

In the prototype PC-HEMT of the present invention, the recessed top layer (12) in the open gate are (17) allows effectively coupling the pyroelectric polarisation to the 2DEG channel. The detector (16) and the 2DEG channel (13) act as two metal plates for the capacitor located in between. Proximity of the detector (16) to the 2DEG channel (13) allows effective coupling of the polarisation, due to incumbent sub-THz or THz radiation. It has been found by the present inventors that there is a perfect synchronicity between the thickness 5-9 nm of the top recessed layer (12) and the 2DEG density. Since effective detector (16) does not require any external power source, the effective 2DEG density plays an important role, on electrically floating gate conditions. In this case, the optimum 2DEG density controlled by the thickness of the top recessed layer (12) is sufficient to induce carrier density perturbations due the net polarisation effects.

The present inventors extensively reviewed the Drude model to check the admittance of both gold and graphene. Moreover, they have modelled the D-S instability equations to analytically determine the effect of a particular frequency (THz) on the 2DEG density.

According to the Drude model, the Drude equation of channel admittance is given by:

$$σ ( ω ) = \frac{{σ}_{0}}{1 - {j ωτ}_{p}}$$

where, ω is the angular frequency, τₚ is the momentum relaxation time, and σ₀=qnₛω is the DC channel conductivity. The admittance values are simulated at 1 THz for 1 μm channel width. The values of σ(DC) for gold and graphene are calculated as 45.45 mho and 1.6 mho, respectively, whereas σ(1 THz) for gold and graphene are calculated to be 0.0725 mho and 0.0896 mho, respectively.

According to the D-S instability Model, the detector response ΔU, which is the constant source-to-drain voltage induced by the incoming THz signal is given by,

$$\frac{Δ U}{{U}_{0}} = \frac{1}{4} {( \frac{{U}_{a}}{{U}_{0}} )}^{2} f ( ω )$$

where, U₀ is the externally applied gate bias, Uₐ is the is the external AC voltage induced between the gate and source by the incoming electromagnetic wave and, f(ω) is the frequency dependent function which is detailed in the D-S model.

It is worth noting that, dependence of the emission spectra on an optimal V_{DS} is extremely critical as D-S instabilities are weakened due to presence of higher source-drain fields. Presence of high localized fields in the channel, overshadows the minor THz field induced, ultimately resulting in inefficient THz detection.

An entire compact model of the PC-HEMT intended towards sub-THz or THz detection is built in the present invention. For this purpose, it has been ensured to build the model right from the basic self-consistent Schrodinger-Poisson model and also the AlGaN/GaN polarisation model. The modelling is done in the following steps:
1) Polarisation induced sheet charge (spontaneous and piezoelectric polarisation) modelling with specific tensors calculated for AlGaN/GaN HEMT on silicon to calculate the 2DEG sheet carrier concentration at AlGaN/GaN HEMT interface.
2) Self-consistent Schrodinger-Poisson equation modelling to calculate the surface potential and on the channel interface, induced by the gate field (THz field and grating gate field).
3) Calculation of the drain current in the linear region (neglecting scattering effects) for further analysis
4) Asymmetric dual grating gate modelling for our HEMT device, to exactly calculate the number of floating gate fingers, their widths and separation distances. This is essential to tune the detector effectively to the THz regime.
5) Analytical estimation of dynamic conductivity of monolayer graphene in response to THz field.
6) Calculation and estimation of responsivity and noise factors of the modelled detector to effectively determine non-equivalent power (NEP) and detection values.

For the sake of brevity, the above modelling steps, extensive calculations and detailed description in this regard will not be described in the present application, but available for review and discussion in the priority application U.S. 62/841,955, the content of which is incorporated herein by reference. The performed analytical calculations allowed the inventors to completely re-design the grating gate which would modulate the 2DEG current at the drain edge at a certain THz standing frequency (f_{fr}). Therefore, upon application of a drain-source potential V_{DS}, it is possible to get a time-varying drain-source current I_{DS}, which would be clocked exactly at this particular frequency.

Reference is now made to FIG. 11a schematically showing a cross-sectional (XZ) view (A-A) of the PC-HEMT of the present invention, with the detector (16) and asymmetric dual grating gate (23) created on top of the detector (16). FIG. 11b schematically shows the top (XY) view and the basic topology of this exemplary transistor. The dual grating gate (23) is made preferably of gold. Bias voltages V_{G1} and V_{G2} can be applied to the odd and even interdigitated gates having lengths L_{G1} and L_{G2}, respectively. Unit cell of the dual grating gate (23) includes ungated region of length Lᵤₙ, which is sandwiched between gated regions with the lengths L_{G1/2} and L_{G2/2}, respectively.

In real structures, the length of ungated regions between the adjacent gates is not small, so that their effect on plasma resonances may be pronounced. In the structures with typical length of ungated 2DEG channel regions of 50 nm to 100 nm, and gate to channel separation d_{G}=50-60 nm, due to fringing, an electric field leaks out rather far from the edges of the gate contacts, so that electron concentration in the fringed ungated 2DEG channel regions can be also controlled by the gate bias voltage. The calculated parameters of the exemplary dual grating gate (23) of the present invention are the length L_{G1}=L_{G2}=100 nm and Lᵤₙ=50 nm, and V_{G1} and V_{G2} are 2 V and 2.5 V, respectively.

Hence, the dual grating gate (23) covers only 10% of the entire gate area and it is placed at the drain edge with the sole intention of creating a standing wave with f_{fr} frequency. The calculated value of f_{fr} in this case is 1.01×10¹² Hz (with periodic number N=3, and gate width and length of 20 μm and 10 μm, respectively). In this simplified structure L_{G1}=L_{G2}, so it will be easier to make the necessary photolithography mask and etch the grating gates.

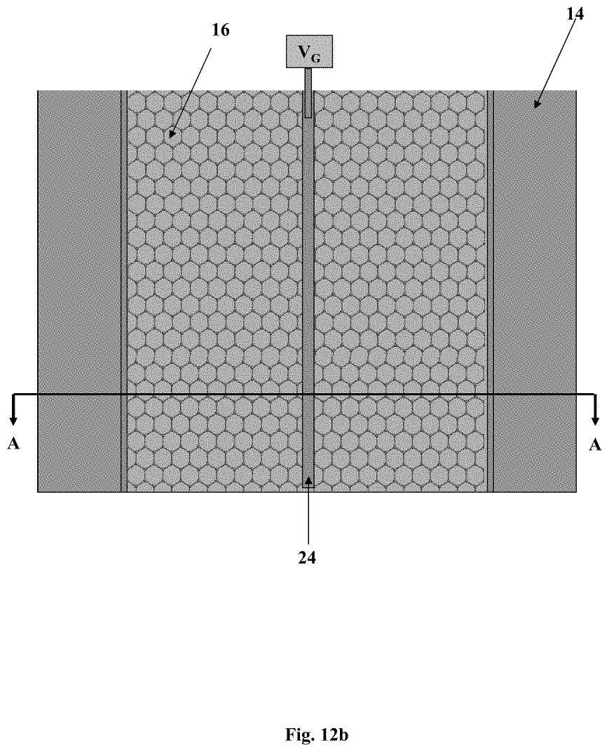

Reference is now made to FIG. 12a schematically showing a cross-sectional (XZ) view (A-A) of the PC-HEMT of the present invention, with the detector (16) and the gate (24) created on top of the detector (16) and preferably made of gold. FIG. 12b schematically shows the top (XY) view and the basic topology of this exemplary transistor.

Resonant absorption of sub-THz and THz radiation by two-dimensional plasmons with collective charge density oscillations of the electrons in the PC-HEMT is the major objective of the present invention. The detector (16) of the present invention has a large area with optionally grating gates. The grating couples incident radiation to specific plasmons with wave vectors determined by the grating period. The plasmon resonant frequency is further determined by the channel electron density which is conveniently tuned by the grating-gate bias.

The PC-HEMT of the present invention has a large open gate (typically 1×1 mm² or even larger) accommodating the detector (16) and a grating period in the order of several microns which is capable of creating plasmon resonance in the sub-THz and THz frequency domain for nominal channel carrier densities in AlGaN/GaN heterostructures.

In the configurations shown in FIGS. 12a-12b, the same concept is used as in the above configurations shown in FIGS. 11a-11b (within a 20 μm×10 μm detector, where the grating structure was used to create standing waves, which amplified the spatially modulated carriers in 2DEG due to the incumbent THz radiation). Enhanced grating-gate detector sensitivity has been achieved in the configuration shown in FIGS. 12a-12b, by integrating a small, separately biased, 100-nm gate strip region, which completely depletes the 2DEG channel of the PC-HEMT locally, while leaving the remaining, much larger, area under the grating gate to be tuned for resonant plasmon absorption of sub-THz or THz radiation. This is accomplished by splitting the gate into sections that can be biased independently. One section consists of a single gate line, which is located in the middle of the transistor. Being biased to full depletion, this small gated element operates as a bolometric sensor. The other gates on either side of this single line are used to tune the plasmon resonance. In principle, in a bolometric mode, sensitivity and time constant can be traded one for the other.

Contrasting the prototype microbolometer, which induces a change in temperature resulting in dynamic resistance due to incumbent sub-THz or THz waves, the same dynamic ΔR can be created across the depleted region, without the dynamic temperature effect. As a result, it is possible to get rid of the read-out IC, and complex microbolometer structures. In this case, one can think about compromising the superior performance of a conventional microbolometer (for example, a focal plane array (FPA)-based microbolometer with V₂O₅ layer) for the sake of cost, size and simplicity. However, since the device is based on the PC-HEMT of the present invention, the unique transistor compensates for those negative effects and still possesses the superior performance.

Thus, the present configuration shown in FIGS. 12a-12b has the essence of a bolometer, but omitting its typical structure. This configuration has a unique combination of THz radiation coupling to the 2DEG aided with monolayer graphene along with ΔR induced by the fully depleted region. In the exemplary configuration, the entire gate area is covered with monolayer graphene, for the reasons explained above. A thin gold strip of 100 nm is placed exactly at L/2, with a bias voltage of V_{G}=−6 V, which ensures proper depletion of the 2DEG channel locally just beneath the gate strip (considering V_{GS}<<V_{T}, where V_{T}=−4.76 V). The rest of this configuration is analogous to the configuration shown in FIGS. 11a-11b above.

### Example: Detection of Fentanyl

Fentanyl is an opioid used as a pain medication and together with other medications for anaesthesia. Fentanyl is also used as a recreational drug, often mixed with heroin or cocaine in drug mixtures. It has a rapid onset and effects generally last less than two hours. Medically, fentanyl is used by injection, as a patch on the skin, as a nasal spray, or in the mouth.

Opioids like fentanyl has very harmful effects targeted towards humans, if exposed to overdose. Even a small quantity of few milligrams of fentanyl can be hazardous. That is why fentanyl bombs sent in post envelopes and parcels by terrorist organizations have become common recently. Detection of a very small amount of fentanyl is thus essential to prevent such cases at earlier stages before the envelopes and parcels are distributed.

Fentanyl absorbs and emits electromagnetic waves (EM) in the range of 1600 cm⁻¹ to 1700 cm⁻¹, with peak frequency clocking at 49.5 THz (mid-infrared regime), and with a bandwidth of 3 THz. The proposed distinctive and robust standalone fentanyl detector method utilises a room temperature operation detector. Its manufacturing does not involve special MEMS capabilities as is usually the case with uncooled micro-bolometric IR detectors. Its architecture incorporates a unique blend of monolayer graphene at the gate of the PC-HEMT of the present invention that is capacity-coupled to the 2DEG channel at the AlGaN/GaN interface. This, along with a depleted mid-channel mimics a micro-bolometer.

Monolayer graphene acts as an excellent Drude absorber layer, effectively absorbing the incoming IR and THz photons by intra-band transitions, thanks to the ultrahigh mobility values of about 4000 cm²/Vs, owing to a greater degrees-of-freedom of carbon atoms. The graphene can be thus capacity-coupled to the 2DEG, which is in turn is depleted at the mid-channel, acting as a resistive element, leading to a time-modulating drain resistance under IR and THz exposure.

IR detection is made super easy and efficient, by the capacitive coupling of the photon induced dynamic graphene carriers to the 2DEG, where the photocurrent gets a very high gain due to the depleted mid-channel resistive element, which also varies spatially in the channel, due to the dynamic 2DEG density. This detector does not require any bias at the gate to drive the transistor, due to the unique quantum behaviour of the PC-HEMT being normally-on and normally-off at the same time, thereby driving its operation by resonance (see the discussion above).

Moreover, the transistor of the present invention introduces a virtual chopper manifested by the intra-band transitions of graphene on exposure to IR, which also enables room temperature operation of the detector and requires less of any mechanical chopper, which is usually required in capacity-based devices such uncooled pyroelectric detectors mentioned above.

In view of the above, the microelectronic sensor of the present invention demonstrated sensitive and specific detection of a paper-based international packaging containing fentanyl in two to three seconds. The sensor can be implemented in a fully automatic system, which requires no operational training and human interaction. Tailoring of responsivity and detection capability of the sensor to 49.5 THz is done by depositing the dielectric band-pass filter (20) on the monolayer graphene (19) (or on the detector's packaging window), provides a significant boost to the sensitivity of the sensor.

The dielectric band-pass filter (20) is an essential element in the detector (16) of the present invention. The major challenge in the PC-HEMT is to reduce the influence of background radiation, to lower down the noise equivalent power (NEP), and thus increase the detection capability. This can be achieved by depositing the dielectric band pass filter (20) on the monolayer graphene (19). Considering any prototype band pass filter, effectively tuned at 49.5 THz, the filter has a minimum bandwidth, and considering this effect, all types of background noises can be neglected.

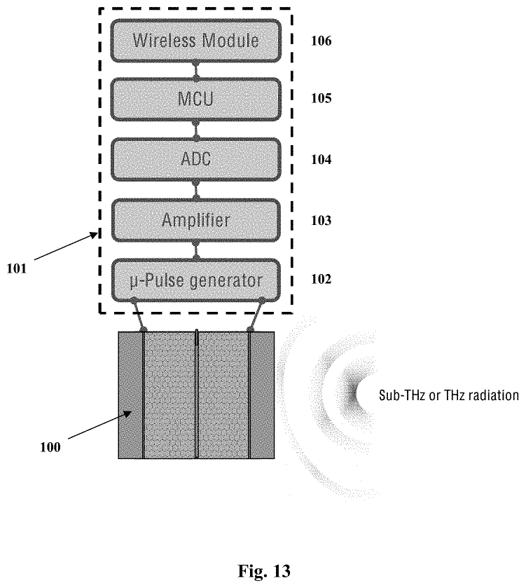

FIG. 13 schematically shows a microelectronic sensor for detection and continuous monitoring of electrical signals in sub-THz and THz frequency ranges from any gas, liquid or solid medium, having a remote readout, and comprising the following components (this is a single-transistor solution):
(a) at least one PC-HEMT (100) of the present embodiments with an integrated bolometric or pyroelectric detector;
(b) an integrated circuit (101) for storing and processing a signal in a sub-THz or THz frequency domain, and for modulating and demodulating a radio-frequency (RF) signals;
(c) an μ-pulse generator (102) for pulsed RF signal generation;
(d) an integrated DC-RF current amplifier or lock-in amplifier (103) connected to said μ-pulse generator (102) for amplification of the signal obtained from said μ-pulse generator;
(e) an analogue-to-digital converter (ADC) (104) with in-built digital input/output card connected to the amplifier (103) for converting the received analogue signal to a digital signal and outputting said digital signal to a microcontroller unit;
(f) the microcontroller unit (MCU) (105) for processing and converting the received digital signal into data readable in a user interface or external memory;
(g) a wireless connection module (106) for wireless connection of said microelectronic sensor to said user interface or external memory.

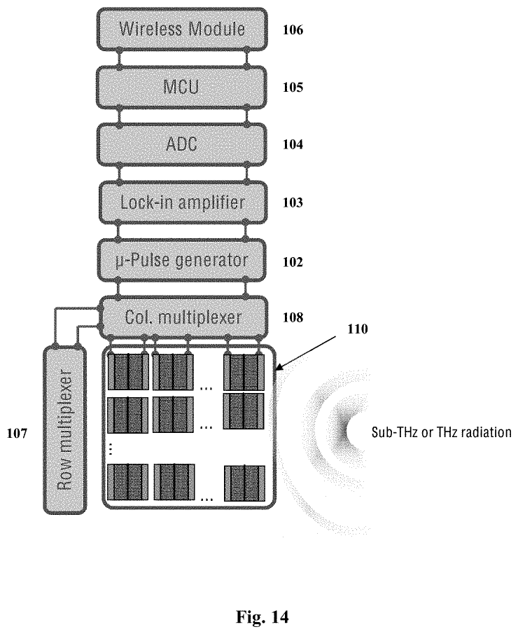

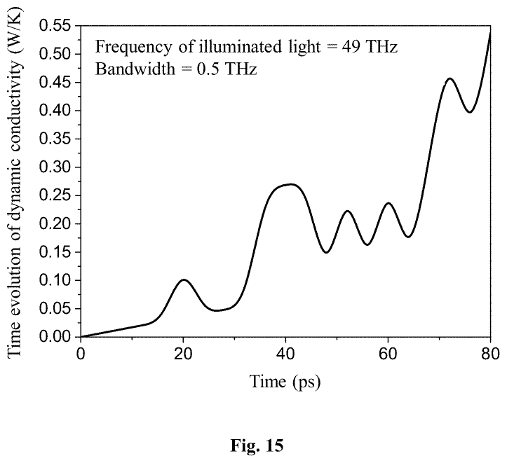

FIG. 14 schematically shows a microelectronic sensor for detection and continuous monitoring of electrical signals in sub-THz and THz frequency ranges, with a remote readout, comprises the following components (this is the DC/RF-based sub-THz and THz antenna transistor-array solution for imaging):
(a) the array of the PC-HEMTs of the present embodiment (110), wherein each PC-HEMT in said array has an integrated bolometric or pyroelectric detector and connected to its dedicated electrical contact line;
(b) a row multiplexer (107) connected to said array for addressing a plurality of said transistors (PC-HEMTs) arranged in rows, selecting one of several analogue or digital input signals and forwarding the selected input into a single line;
(c) a column multiplexer (108) connected to said array for addressing a plurality of said transistors (PC-HEMTs) arranged in columns, selecting one of several analogue or digital input signals and forwarding the selected input into a single line;
(d) an integrated circuit for storing and processing said signals in a sub-THz or THz frequency domain, and for modulating and demodulating a radio-frequency (RF) signals;
(e) an μ-pulse generator (102) for pulsed RF signal generation;
(f) an integrated DC-RF current amplifier or lock-in amplifier (103) connected to said μ-pulse generator (102) for amplification of the signal obtained from said μ-pulse generator;
(g) an analogue-to-digital converter (ADC) (104) with in-built digital input/output card connected to the amplifier (103) for converting the received analogue signal to a digital signal and outputting said digital signal to a microcontroller unit;
(h) the microcontroller unit (MCU) (105) for processing and converting the received digital signal into data readable in a user interface or external memory;
(i) a wireless connection module (106) for wireless connection of said microelectronic sensor to said user interface or external memory.

The ADC card (104) may be any suitable analogue-to-digital converter data logger card that can be purchased, for example, from National Instruments® or LabJack®. Optionally, the current amplifier (103) can be operated directly with current flowing via the 2DEG/2DHG channel into the amplifier with small input resistance of 1MΩ at gain higher than 10⁴ and only 1Ω at gains lower than 200. This setup may directly amplify the electric current modulation in the 2DEG channel originated from an external body charges.

In a specific embodiment, the wireless connection module may be a short-range Bluetooth® or NFC providing wireless communication between the sensor and the readout module for up to 20 m. If this connection module is Wi-Fi, the connection can be established with a network for up to 200 nm, while GSM allows the worldwide communication to a cloud. The external memory may be a mobile device (such as a smartphone), desktop computer, server, remote storage, internet storage or cloud.

In some embodiments, the sensors of the present invention can be used for portable long-time-operation solution within remote cloud-based service. The portable sensor of an embodiment should have a very small power consumption saving the battery life for a prolong usage. In this case, the non-ohmic high-resistive contacts capacitively connecting the sensor to an electric circuit are preferable. The non-ohmic contacts limit electric current flowing through the 2DEG/2DHG channel by having an electrical resistance 3-4 times higher than the resistance of the 2DEG/2DHG-channel, thereby reducing electrical power consumption without sacrificing sensitivity and functionality of the sensor. Thus, the use of non-ohmic contacts in some embodiments of the sensor of the present application is a hardware solution allowing to minimise the power consumption of the device. In another embodiment, the power consumption of the device can be minimised using a software algorithm managing the necessary recording time of the sensor and a battery saver mode, which limits the background data and switches the wireless connection only when it is needed.

In some embodiments, a method for chemical sensing and biomolecular diagnostics comprises the following steps:
(1) Subjecting a sample to be tested to the microelectronic senor of the present embodiments;
(2) Recording electrical signals in the frequency range between 30 GHz to 430 THz received from the sample with the microelectronic sensor in a form of a source-drain electric potential of the microelectronic sensor over time (V_{DS} dynamics) or measuring S11-S12 parameters of the microelectronic sensor over time (S11-S12 dynamics);
(3) Transmitting the recorded signals from said microelectronic sensor to an external memory for further processing; and
(4) Converting the transmitted signals to digital signals and processing the digital signals in the external memory, comparing said V_{DS} dynamics or S11-S12 dynamics with negative control chemical or biomolecular V_{DS} or S11-S12 waveforms stored in the external memory, and extracting chemical or biomolecular information from said waveforms in a form of readable data, thereby detecting and identifying a particular chemical or biological analyte in the sample and optionally determining its concentration or amount.

### EVALUATIONS AND CONCLUSIONS

Thus, the entire concept of the present invention revolves around the following five main points, which allow achieving amazing functionality of the transistor and sensor of the present invention with a simple yet unconventional engineering approach.

1. Combining the PC-HEMT with the Bolometric or Pyroelectric Detector

The PC-HEMTs developed by the present inventors have a high 2DEG channel density, which is approximately 10¹³ cm⁻², along with the low normally-on state channel resistance, which is approximately 100 mΩ/mm, and appreciable Hall mobility (about 1700 cm²/V·s) owing to the strong spontaneous and piezoelectric polarisation (about 3 MV/cm), large saturation velocity, high breakdown voltage, and ability to operate at high temperatures. The PC-HEMTs are therefore the most promising devices for high-frequency, high-power, and high temperature applications.

### 2. Using Metamaterials, Such as Graphene, in Effectively Detecting Sub-THz and THz Radiation

Capacitive coupling of the 2DEG with a monolayer metamaterial, such as graphene, in the open gate, is the new state of the art concept for efficient sub-THz and THz detection. As an example of a metamaterial used in the present invention, graphene is a two-dimensional crystal of carbon atoms packed in a honeycomb lattice, which offers efficient platform for strong light-matter interaction, due to its intrinsic high mobility and chiral electronic spectrum. Recent progress on back-gated and top-gated graphene-HEMT integration with high-k dielectric (Al₂O₃), has achieved mobility of over 4000 cm²/V·s at high charge density and 40,000 cm²/Vs at low charge density, making graphene a potential candidate for sub-THz and THz nano-electronics.

Therefore, when the ultra-high mobile monolayer graphene is capacitively coupled to the highly mobile 2DEG channel of the PC-HEMT, the 2DHG pseudoconductive current is immediately induced in the graphene layers. In principle, the free carrier density in graphene can be tuned by several orders of magnitude (about 10¹¹ to 10¹⁴ cm⁻²). Such unique property allows one to strongly control the plasma waves' response in the sub-THz and THz frequency range. Thus far, all the experimental studies performed by the present inventors confirmed the following theoretical expectations.

First, inter-band transitions (between the valence band to the conduction band) dominate in the near-infrared/visible range, resulting in a known constant light absorption of about 2.3% by a single-layer metamaterial, such as graphene, at normal incidence. Second, intra-band transitions (within the conduction or valence band) dominates in the sub-THz and THz frequency range, resulting in an optical conductivity well described by the Drude model. By tuning the Fermi level in a metamaterial, such as graphene, the density of states can also be tuned. These states are available for intra-band transitions under sub-THz and THz range irradiation, which makes it possible to tune the effective sub-THz and THz absorption of about 75% to 76.5% through the graphene monolayer.

In the sub-THz and THz range, where intra-band transitions actually dominate, the metamaterial, such as graphene, behaves like a conductive film, and its optical conductivity closely follows its electrical conductivity. Optical conductivity can be described by a simple Drude model of the form:

$$σ ( ω ) = \frac{{σ}_{DC} ( {E}_{F} )}{1 + {ω}^{2} {τ}^{2}}$$

where σ_{DC}(E_{F}) represents the DC electrical conductivity and T is the carrier momentum scattering time.

As suggested by the above equation, sub-THz and THz absorption in the metamaterial can be modulated by tuning its electrical conductivity or Fermi level at one of the following set of conditions: 1) when ωτ<<1, and σ(ω) is approximately equal to σ_{DC}(E_{F}), or 2) when ωτ>1, and σ(ω)<σ_{DC}(E_{F}).

With particular regard to graphene, due to the presence of this excellent intra-band transition property of graphene, which is essentially a room temperature phenomenon, graphene is chosen as an exemplary metamaterial for the gate to build an efficient room temperature fentanyl detector. A quantity that determines the gain at frequency ω is the real part of the net dynamic conductivity Reσ_{ω} consisting of the intra-band Reσ_{ω}^{intra} and the inter-band Reσ_{ω}^{inter} contributions where the negative values of Reσ_{ω} gives the gain. Reσ_{ω} is proportional to the absorption of photons with frequency ω and given by:

$${Re σ}_{ω} = {Re σ}_{ω}^{inter} + {Re σ}_{ω}^{intra} = \frac{{q}^{2} π}{2 h} ( 1 + 2 f ) + \frac{( ln2 + {ɛ}_{F} / 2 {k}_{b} T ) {q}^{2} π}{2 h} \frac{2 {π k}_{b} T}{h ( 1 + {ω}^{2} {τ}^{2} )}$$

where h is the Planks constant and k_{b} is the Boltzmann constant.

Simulated results obtained by the present inventors for Reσ_{ω} are shown in FIG. 15, as functions of time and frequency with momentum relaxation time of 10 ps. In fact, this figure shows the time evolution of dynamic conductivity of graphene. Typically, this intra-band transitions have a time constant in the range of milliseconds, provided, the Dirac point is effectively tuned of the monolayer graphene. In absence of any applied bias, the graphene sheet with the effectively tailored Dirac point, will absorb the sub-THz and THz radiation, and transform it into a spatially modulating charge carriers due to a plethora of intra-band transitions happening at KHz frequency.

To sum up, the metamaterial sheet acts as a perfect chopper for the capacitively coupled metamaterial/2DEG channel, relinquishing any need of an external chopper.

### 3. Physics Behind Depleting the 2DEG Channel

Enhanced sensor sensitivity has been achieved in the present invention, by integrating a separately biased, approximately 200-nm in width gate strip region deposited on the metamaterial gate, which completely depletes locally underneath the 2DEG channel of the PC-HEMT, while leaving the remaining, much larger area under the open gate to be tuned for capacitively coupled plasmon absorption of sub-THz and THz radiation. This is accomplished by splitting the open gate into two sections that can be utilized independently.

One section consists of a single gate line that is located in the middle of the device, biased to full depletion. This small gated element operates as a bolometric detector. The open gate area on either side of this single line is used to tune the plasmon resonance, without the need of any external bias. External bias is provided on across the metamaterial layer by depositing thin metal contacts on both edges of the metamaterial sheet, in order to effectively tailor the Dirac point for the millisecond intra-band transitions, if and only if, the metamaterial transfer process is not flawless. Thin Au strip of approximately 200 nm is placed exactly at L/2, with a bias of −6V, which ensures proper depletion of the channel locally just beneath the gate strip (considering V_{G}<<V_{T}, where V_{T} is equal to −4.76V in the exemplary PC-HEMT of the present invention). This engineered transistor is therefore a split-gate PC-HEMT double potential well (DPW), capacity-coupled with modulating metamaterial charge carriers. Each well is of about 5 μm length separated by about 200 nm width barrier.

The DPW is calculated using the self-consistent Schrodinger-Poisson model, assuming negligible charge carrier density in the depleted region. Calculations are performed to evaluate the residual drain current, I_{DS}, and hence the net change in resistance ΔR_{DS} across the barrier.

4. How does the Aforementioned Physics Integrate to Form an Efficient Sensor?

At the final stage, all the above calculations have been integrated to eventually calculate the residual detector response ΔU and ΔR_{DS}. This is a unique form of visualisation of charge carriers where, one could effectively model the spatial variation of the 2DEG channel and dynamic width of the depleted region (resulting in dynamic R_{DS}), when provided with a constant electric field, for example V_{DS}=1 V, which extracts the time-modulated charge carriers from the drain edge.

In the above example on fentanyl detection, the modulation frequency of graphene intra-band transitions on exposure to fentanyl's 49.5 THz radiation is precisely calculated to be 40 KHz by perfectly tailoring the Dirac point of monolayer graphene. The Dirac point will remain as desired provided the graphene transfer process is flawless. This spatially modulated 2DHG charge carriers are then capacitively coupled to the 2DEG channel. The dynamic 2DHG channel conductivity is fed to the self-consistent Poisson-Schrodinger equation in order to obtain a dynamic surface potential at the AlGaN/GaN interface. This dynamic surface potential is integrated along the channel with a new boundary at L=5 μm on either sides. The spatially modulated charge carriers with the influence of the sub-THz and THz radiation, faces a high field barrier at the middle of the channel. In this way a dynamic I_{DS} is obtained across the entire channel that is due to a dynamic R_{DS}.

Ignoring scattering effects, it is possible to presume that the entire ΔR_{DS} is due to the spatially modulating depleted channel width at the middle, as the rest of the channel length is filled with the 2DEG. As a result, the inventors were able to obtain a significant gain on the dynamic drain voltage (ΔV_{DS}) which is a product of the dynamic ΔI_{DS} and ΔR_{DS}, thanks to the depleted micro-bolometer like channel unit. Hence, they were able to extract residual ΔU in the range of few volts, and ΔR_{DS} in the range of 100 S2's. This analysis provides state-of-the-art sensor parameters, with the huge ΔV=1.57 V across the depleted region.

### 5. The Final Detector Parameter Calculations

To calculate the responsivity of the sensor, the input sub-THz or THz flux (field) needs to be estimated. The input flux is approximated as a radiation from a tested material (analyte, for example, fentanyl) with the typical temperatures of 300 K. The performed calculation results in the input flux value of Φᵢₙₚᵤₜ=1.1969×10⁻¹⁰ W, over an area of 10 μm×20 μm. If the emission spectrum of the analyte is not identical to the absorption spectra, then very minimal changes in the geometrical dimensions of the transistor need to be computed.

In the example with fentanyl, the analysis performed by the present inventors revealed that Rv=9.5861×10⁷ V/W. For calculation of the noise equivalent power (NEP), detection ability and dynamic range (DR), the quantum noise or commonly referred as Shot noise, due to the presence of the filter, were only taken into account. This enormous feat of engineering has rendered outstanding results compared to any current state-of-the-art sub-THz and THz sensors. The obtained NEP is 2.1694×10⁻¹⁶ W/√Hz, detection ability D* is 2.147×10¹⁰ cm√Hz/W and DR is 112.32 dB or 413 bits. Absence of any micro-bolometer unit with a readout integrated circuit added with absence of a chopper and no requirement for gate drive voltage, makes the sensor of the present invention of the best standalone uncooled sensor modelled for sub-THz and THz detection, taking into account the simplicity of its design, lower operational power, and reduced cost of manufacturing.

Thus, the major building blocks of the sensor of the present invention are:
The metamaterial layer, such as graphene for room temperature detection and manifestation of virtual chopper due to intra-band transitions in the sub-THz and THz spectrum.
The PC-HEMT of the present inventors, due to presence of highly mobile 2DEG/2DHG channel.

The depleted 2DEG or 2DHG channel of the PC-HEMT allows to mimic a resistive bolometric or pyroelectric element, offering gain to time-modulated 2DEG/2DHG, and removing the complexity of microbolometer or pyroelectric detector with the readout integrated circuit. Optionally, a dielectric filter can be introduced into the sensor of the present invention to effectively tune the incident radiation to the THz spectra of the tested material or analyte.

1. An open-gate pseudo-conductive high-electron mobility transistor for amplifying signals in the frequency range of 30 GHz to 430 THz, comprising:
(1) a multilayer hetero-junction structure made of gallium nitride (GaN) and aluminium gallium nitride (AlGaN) single-crystalline or polycrystalline semi-conductor materials, deposited on a substrate layer (10) or placed on a free-standing membrane (21), said structure comprising at least one GaN layer (11) and at least one AlGaN layer (12), said layers being stacked alternately;
(2) a conducting channel (13) comprising a two-dimensional electron gas (2DEG) or a two-dimensional hole gas (2DHG), formed at the interface between said GaN layer (11) and said AlGaN layer (12), and upon applying a bias to said transistor, providing electron or hole current, respectively, in said transistor between source and drain contacts (15);
(3) the source and drain contacts (15) connected to said 2DEG or 2DHG conducting channel (13) and to electrical metallisations (14) for connecting said transistor to an electric circuit; and
(4) a bolometric or pyroelectric detector (16) placed on a top layer (GaN or AlGaN) between said source and drain contacts (15) in an open gate area (17) of the transistor, and suitable for detecting electrical signals in the frequency range of 30 GHz to 430 THz;
wherein thickness of the top layer (GaN or AlGaN) of said heterojunction structure in the open gate area (17) is about 5-9 nanometres (nm) and surface roughness of said top layer is about 0.2 nm or less,
wherein the combination of said thickness and said roughness of the top layer creates a quantum electronic effect of operating said 2DEG or 2DHG channel (13) simultaneously in both normally-on and normally-off operation modes of the channel, thereby making the transistor suitable for conducting electric current through said channel in a quantum well between normally-on and normally-off operation modes of the transistor.

2. The transistor of claim 1, wherein said hetero-junction structure comprises:
A. (i) one top AlGaN barrier layer recessed in an open gate area of the transistor to the thickness of 5-9 nm and having the surface roughness of 0.2 nm or less, and (ii) one bottom GaN buffer layer; said layers have Ga-face polarity, thus forming the two-dimensional electron gas (2DEG) conducting channel in said GaN layer, close to the interface with said AlGaN layer; or
B. (i) one top GaN layer recessed in an open gate area of the transistor to the thickness of 5-9 nm and having the surface roughness of 0.2 nm or less, (ii) one bottom GaN buffer layer, and (iii) one AlGaN barrier layer in between; said layers have Ga-face polarity, thus forming a two-dimensional hole gas (2DHG) conducting channel in the top GaN layer, close to the interface with said AlGaN barrier layer; or
C. (i) one top GaN layer recessed in an open gate area of the transistor to the thickness of 5-9 nm and having the surface roughness of 0.2 nm or less, (ii) one bottom GaN buffer layer, and (iii) one AlGaN barrier layer in between; said layers have N-face polarity, thus forming a two-dimensional electron gas (2DEG) conducting channel in the top GaN layer, close to the interface with said AlGaN barrier layer; or
D. (i) one top AlGaN layer recessed in an open gate area of the transistor to the thickness of 5-9 nm and having the surface roughness of 0.2 nm or less, and (ii) one bottom GaN buffer layer; said layers have N-face polarity, thus forming a two-dimensional hole gas (2DHG) conducting channel in the GaN buffer layer, close to the interface with said AlGaN barrier layer.

3. The transistor of claim 1, further comprising an asymmetric dual grating gate (23) created on top of the detector (16).

4. The transistor of claim 1, further comprising a separately-biased grating gate (24) created on top and in the middle of the detector (16), said grating gate (24) is capable of completely depleting the 2DEG or 2DHG conducting channel (13) locally, while leaving the remaining area under the grating gate (24) to be tuned for resonant plasmon absorption of sub-THz or THz radiation.

5. The transistor of claim 1, further comprising at least one chemical or biomolecular layer immobilised on the detector (16) within the open gate area (17) of said transistor and capable of binding or adsorbing target (analyte) gases, chemical compounds or biomolecules from the environment.

6. The transistor of claim 5, wherein said at least one chemical or biomolecular layer is cyclodextrin, 2,2,3,3-tetrafluoropropyloxy-substituted phthalocyanine or their derivatives, or said chemical or biomolecular layer comprises capturing biological molecules, such as primary, secondary antibodies or fragments thereof against certain proteins to be detected, or their corresponding antigens, enzymes or their substrates, short peptides, specific polynucleotide sequences, which are complimentary to the sequences of DNA to be detected, aptamers, receptor proteins or molecularly imprinted polymers.

7. The transistor of claim 1, wherein the thickness of the top layer of the transistor in the open gate area is about 6-7 nm, or 6.2 nm to 6.4 nm.

8. The transistor of claim 7, wherein said top layer has the roughness of about 0.1 nm or less, or 0.05 nm or less.

9. The transistor of claim 1, wherein said source and drain contacts are ohmic.

10. The transistor of claim 1, wherein said electrical metallisations are capacitively-coupled to said 2DEG or 2DHG conducting channel for inducing displacement currents, thus resulting in said source and drain contacts being non-ohmic.

11. The transistor of claim 1, further comprising a dielectric layer deposited on top of said multilayer hetero junction structure.

12. The transistor of claim 1, wherein said bolometric or pyroelectric detector (16) comprises a metamaterial selected from graphene, carbon nanotubes, graphene/gold or copper/single layer graphene/copper composite, said metamaterial is suitable for creating a metasurface designed to modulate (allow or inhibit) propagation of electromagnetic waves in desired directions.

13. The transistor of claim 1, wherein said bolometric or pyroelectric detector comprises a graphene layer (19) coated with a dielectric band-pass filter (20) and deposited on an alumina layer (18).

14. The transistor of claim 1, wherein said pyroelectric detector comprises LiTaO₃/BaTiO₃ crystals.

15. A microelectronic sensor for chemical sensing and biomolecular diagnostics in the frequency range of 30 GHz to 430 THz, with a remote readout, comprising:
(a) at least one transistor (100) of claim 1;
(b) an integrated circuit (101) for storing and processing a signal in a sub-THz or THz frequency domain, and for modulating and demodulating a radio-frequency (RF) signals;
(c) an μ-pulse generator (102) for pulsed RF signal generation;
(d) an integrated DC-RF current amplifier or lock-in amplifier (103) connected to said μ-pulse generator (102) for amplification of the signal obtained from said μ-pulse generator;
(e) an analogue-to-digital converter (ADC) (104) with in-built digital input/output card connected to the amplifier (103) for converting the received analogue signal to a digital signal and outputting said digital signal to a microcontroller unit;
(f) the microcontroller unit (MCU) (105) for processing and converting the received digital signal into data readable in a user interface or external memory; and
(g) a wireless connection module (106) for wireless connection of said microelectronic sensor to said user interface or external memory.

16. A microelectronic sensor for chemical sensing and biomolecular diagnostics in the frequency range of 30 GHz to 430 THz, with a remote readout, comprising:
(a) an array (110) of the transistors of claim 1, wherein each transistor in said array is connected to its dedicated electrical contact line;
(b) a row multiplexer (107) connected to said array for addressing a plurality of said transistors arranged in rows, selecting one of several analogue or digital input signals and forwarding the selected input into a single line;
(c) a column multiplexer (108) connected to said array for addressing a plurality of said transistors arranged in columns, selecting one of several analogue or digital input signals and forwarding the selected input into a single line;
(d) an integrated circuit for storing and processing said signals in a sub-THz or THz frequency domain, and for modulating and demodulating a radio-frequency (RF) signals;
(e) an μ-pulse generator (102) for pulsed RF signal generation;
(f) an integrated DC-RF current amplifier or lock-in amplifier (103) connected to said μ-pulse generator (102) for amplification of the signal obtained from said μ-pulse generator;
(g) an analogue-to-digital converter (ADC) (104) with in-built digital input/output card connected to the amplifier (103) for converting the received analogue signal to a digital signal and outputting said digital signal to a microcontroller unit;
(h) the microcontroller unit (MCU) (105) for processing and converting the received digital signal into data readable in a user interface or external memory; and
(i) a wireless connection module (106) for wireless connection of said microelectronic sensor to said user interface or external memory.

17. A method for chemical sensing and biomolecular diagnostics of a particular analyte in a sample, said method comprising:
(1) Subjecting the sample to a microelectronic senor comprising at least one transistor of claim 1;
(2) Recording electrical signals in the frequency range between 30 GHz to 430 THz received from the sample with the microelectronic sensor in a form of a source-drain electric potential of the microelectronic sensor over time (V_{DS} dynamics) or measuring S11-S12 parameters of the microelectronic sensor over time (S11-S12 dynamics);
(3) Transmitting the recorded signals from said microelectronic sensor to an external memory for further processing; and
(4) Converting the transmitted signals to digital signals and processing the digital signals in the external memory, comparing said V_{DS} dynamics or S11-S12 dynamics with negative control chemical or biomolecular V_{DS} or S11-S12 waveforms stored in the external memory, and extracting chemical or biomolecular information from said waveforms in a form of readable data, thereby detecting and identifying the particular analyte in the sample and optionally determining its concentration or amount.

18. The method of claim 17, wherein the sample is in a gas phase or in a liquid phase.

19. The method of claim 17, wherein said analyte is selected from the group of:
toxic metals, such as chromium, cadmium or lead,
regulated ozone-depleting chlorinated hydrocarbons,
food toxins, such as aflatoxin, and shellfish poisoning toxins, such as saxitoxin or microcystin,
neurotoxic compounds, such as methanol, manganese glutamate, nitrix oxide, tetanus toxin or tetrodotoxin, Botox, oxybenzone, Bisphenol A, or butylated hydroxyanisole,
explosives, such as picrates, nitrates, trinitro derivatives, such as 2,4,6-trinitrotoluene (TNT), 1,3,5-trinitro-1,3,5-triazinane (RDX), trinitroglycerine, N-methyl-N-(2,4,6-trinitrophenyl)nitramide (nitramine or tetryl), pentaerythritol tetranitrate (PETN), nitric ester, azide, derivates of chloric and perchloric acids, fulminate, acetylide, and nitrogen rich compounds, such as tetrazene, octahydro-1,3,5,7-tetranitro-1,3,5,7-tetrazocine (HMX), peroxide, such as triacetone trioxide, C4 plastic explosive and ozonidesor, or an associated compound of said explosives, such as a decomposition gases or taggants, and
biological pathogens, such as a respiratory viral or bacterial pathogen, an airborne pathogen, a plant pathogen, a pathogen from infected animals or a human viral pathogen.

20. The method of claim 19, wherein said viral pathogen is SARS-CoV-2.
